(19) United States
(12) Patent Application Publication
(10) Pub. No.: US 2025/0038011 A1
(43) Pub. Date: Jan. 30, 2025

(54) SUBSTRATE PROCESSING TOOL WITH RAPID AND SELECTIVE CONTROL OF PARTIAL PRESSURE OF WATER VAPOR AND OXYGEN

(71) Applicant: LAM RESEARCH CORPORATION, Fremont, CA (US)

(72) Inventors: Richard H. GOULD, Bedford, TX (US); Karl Frederick LEESER, West Linn, OR (US); Michael NORDIN, San Jose, CA (US); Jose VELASCO, San Jose, CA (US)

(21) Appl. No.: 18/706,772

(22) PCT Filed: Nov. 1, 2022
(86) PCT No.: PCT/US2022/048562

§ 371 Date: May 2, 2024

Related U.S. Application Data
(60) Provisional application No. 63/275,299, filed on Nov. 3, 2021.

(51) Int. Cl. H01L 21/67

(52) U.S. Cl. CPC H01L 21/67017; H01L 21/67167

(57) ABSTRACT

A substrate processing tool includes: a first processing module; a vacuum transfer module connected to the first processing module; one or more pumps; a backfill source; and one or more controllers. The one or more controllers are configured to: control the one or more pumps to reduce a chamber pressure in the vacuum transfer module from a first chamber pressure to a second chamber pressure and then backfill the vacuum transfer module with an inert gas to a third chamber pressure prior to permitting transfer of a substrate into the first processing module; subsequent to backfilling the vacuum transfer module, cause a transfer of the substrate from the vacuum transfer module to the first processing module; and cause the first processing module to process the substrate.

### CROSS-REFERENCE TO RELATED APPLICATIONS

This application claims the benefit of U.S. Provisional Application No. 63/275,299, filed on Nov. 3, 2021. The entire disclosure of the above application is incorporated herein by reference.

### FIELD

The present disclosure relates to substrate processing tools including processing modules performing different substrate processes.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A substrate processing system may be used to perform deposition, etch and/or other treatments of substrates such as semiconductor wafers. During processing, a substrate is arranged on a substrate support in a processing chamber of the substrate processing system. Gas mixtures including one or more precursors may be introduced into the processing chamber and plasma may be struck to activate chemical reactions.

The substrate processing system may include substrate processing tools arranged within a fabrication room. Each of the substrate processing tools may include multiple process modules or chambers. Each of the processing tools performs a single type of process, such as a clean, deposition or etch process. Substrates are transferred into a substrate processing tool through one or more intermediate chambers, such as front opening unified pods (FOUPs), an equipment front end module (EFEM), and/or load locks. The substrates are transferred between process modules within a vacuum transfer module (VTM).

### SUMMARY

A substrate processing tool is disclosed and includes: a first processing module; a vacuum transfer module connected to the first processing module; one or more pumps; a backfill source; and one or more controllers. The one or more controllers are configured to: control the one or more pumps to reduce a chamber pressure in the vacuum transfer module from a first chamber pressure to a second chamber pressure and then backfill the vacuum transfer module with an inert gas to a third chamber pressure prior to permitting transfer of a substrate into the first processing module; subsequent to backfilling the vacuum transfer module, cause a transfer of the substrate from the vacuum transfer module to the first processing module; and cause the first processing module to process the substrate.

In other features, the substrate processing tool further includes valves connected to the one or more pumps and the backfill source. The one or more controllers are configured to control the one or more pumps and the valves to reduce the chamber pressure in the vacuum transfer module from the first chamber pressure to the second chamber pressure and then backfill the vacuum transfer module with the inert gas to the third chamber pressure prior to permit transfer of the substrate into the first processing module.

In other features, the one or more pumps include a first pump. The valves include a first valve connected to the first pump and the vacuum transfer module. The one or more controllers are configured to control a state of the first valve to pump down to the second chamber pressure.

In other features, the one or more pumps include a second pump. The valves include a second valve connected to the second pump. The one or more controllers are configured to control a state of the second valve to pump down to the first chamber pressure.

In other features, the one or more controllers are configured to control at least one of the state of the first valve and the state of the second valve to pump down from the first chamber pressure to a fourth chamber pressure. The fourth chamber pressure is less than the first chamber pressure and greater than the second chamber pressure. The one or more controllers are configured to control the state of the first valve and close the second valve to pump down to the second chamber pressure.

In other features, the substrate processing tool further includes a mass flow controller. One of the valves is connected in series with the mass flow controller and between the backfill source and the vacuum transfer module. The mass flow controller is configured to adjust flow of the inert gas from the backfill source to the vacuum transfer module. The one or more controllers are configured to control operation of the mass flow controller and the one of the valves to supply the inert gas to backfill the vacuum transfer module to the third chamber pressure.

In other features, the substrate processing tool further includes processing modules including the first processing module and a second processing module. The processing modules are configured to perform different respective types of substrate processing. The vacuum transfer module is connected to the processing modules. The vacuum transfer module is configured to transfer the substrate from the first processing module to the second processing module.

In other features, the first processing module is configured to pre-clean the substrate. The second processing module is configured to perform a deposition process.

In other features, the one or more controllers are configured to (i) permit transfer of the substrate into the first processing module when an interior of the vacuum transfer module is at the third chamber pressure, (ii) backfill the vacuum transfer module to the first chamber pressure, and (ii) permit transfer of the substrate from the first processing module to the second processing module when the interior of the vacuum transfer module is at the first chamber pressure.

In other features, the one or more controllers are configured to provide a continuous purge flow of backfill gas to the interior of the vacuum transfer module to dilute and reduce one or more partial pressures of one or more contaminant gases in the interior of the vacuum transfer module.

In other features, the one or more controllers are configured to control operation of one of the valves to supply the inert gas to the vacuum transfer module while transferring the substrate between the processing modules and the vacuum transfer module.

In other features, the one or more controllers are configured to: while reducing the chamber pressure in the vacuum transfer module, control the one or more pumps and the valves to reduce a partial pressure of oxygen (PP O₂) in the vacuum transfer module from a first PP O₂ to a second PP O₂; and while backfilling the vacuum transfer module to the third chamber pressure, backfill the vacuum transfer module to a third PP O₂ prior to permitting transfer of the substrate into the first processing module.

In other features, the one or more controllers are configured to adjust the PP O₂ in the vacuum transfer module based on the chamber pressure of the vacuum transfer module. In other features, the third PP O₂ is less than or equal to 1e−5 T.

In other features, the one or more pumps include a first pump. The valves include a first valve connected to the first pump and the vacuum transfer module. The one or more controllers are configured to control a state of the first valve to pump down to the second PP O₂.

In other features, the one or more pumps include a second pump. The valves include a second valve connected to the second pump. The one or more controllers are configured to control a state of the second valve to pump down to the first PP O₂.

In other features, the one or more controllers are configured to control at least one of the state of the first valve and the state of the second valve to pump down from the first PP O₂ to a fourth PP O₂. The fourth PP O₂ is less than the first PP O₂ and greater than the second PP O₂. The one or more controllers are configured to control the state of the first valve and close the second valve to pump down to the second PP O₂.

In other features, the substrate processing tool further includes a mass flow controller. One of the valves is connected in series with the mass flow controller and between the backfill source and the vacuum transfer module The mass flow controller is configured to adjust flow of the inert gas from the backfill source to the vacuum transfer module. The one or more controllers are configured to control operation of the mass flow controller and the one of the valves to supply the inert gas to backfill the vacuum transfer module to the third PP O₂.

In other features, the substrate processing tool further includes processing modules including the first processing module and a second processing module. The processing modules are configured to perform different respective types of substrate processing. The vacuum transfer module is connected to the processing modules. The vacuum transfer module is configured to transfer the substrate from the first processing module to the second processing module.

In other features, the one or more controllers are configured to (i) permit transfer of the substrate into the first processing module when an interior of the vacuum transfer module is at the third PP O₂, (ii) backfill the vacuum transfer module to the first PP O₂, and (ii) permit transfer of the substrate from the first processing module to the second processing module when the interior of the vacuum transfer module is at the first PP O₂.

In other features, the one or more controllers are configured to: while reducing the chamber pressure in the vacuum transfer module, control the one or more pumps and the valves reduce a partial pressure of water vapor (PP H₂O) in the vacuum transfer module from a first PP H₂O to a second PP H₂O; and while backfilling the vacuum transfer module to the third chamber pressure, control the valves to backfill the vacuum transfer module to a third PP H₂O prior to permitting transfer of the substrate into the first processing module.

In other features, the one or more controllers are configured to adjust the PP H₂O in the vacuum transfer module based on the chamber pressure of the vacuum transfer module. In other features, the third PP H₂O is less than or equal to 4e−6 T.

In other features, the one or more pumps include a first pump. The valves include a first valve connected to the first pump and the vacuum transfer module. The one or more controllers are configured to control a state of the first valve to pump down to the second PP H₂O.

In other features, the one or more pumps include a second pump. The valves include a second valve connected to the second pump. The one or more controllers are configured to control a state of the second valve to pump down to the first PP H₂O.

In other features, the one or more controllers are configured to control at least one of the state of the first valve and the state of the second valve to pump down from the first PP H₂O to a fourth PP H₂O. The fourth PP H₂O is less than the first PP H₂O and greater than the second PP H₂O. The one or more controllers are configured to control the state of the first valve and close the second valve to pump down to the second PP H₂O.

In other features, the substrate processing tool further includes a mass flow controller. One of the valves is connected in series with the mass flow controller and between the backfill source and the vacuum transfer module The mass flow controller is configured to adjust flow of the inert gas from the backfill source to the vacuum transfer module. The one or more controllers are configured to control operation of the mass flow controller and the one of the valves to supply the inert gas to backfill the vacuum transfer module to the third PP H₂O.

In other features, the substrate processing tool further includes processing modules including the first processing module and a second processing module. The processing modules are configured to perform different respective types of substrate processing. The vacuum transfer module is connected to the processing modules. The vacuum transfer module is configured to transfer the substrate from the first processing module to the second processing module.

In other features, the one or more controllers are configured to (i) permit transfer of the substrate into the first processing module when an interior of the vacuum transfer module is at the third PP H₂O, (ii) backfill the vacuum transfer module to the first PP H₂O, and (ii) permit transfer of the substrate from the first processing module to the second processing module when the interior of the vacuum transfer module is at the first PP H₂O.

In other features, the one or more controllers are configured to: while reducing the chamber pressure in the vacuum transfer module, further control the one or more pumps and the valves to reduce a PP O₂ in the vacuum transfer module from a first PP O₂ to a second PP O₂; and while backfilling the vacuum transfer module to the third chamber pressure, further control the valves to backfill the vacuum transfer module to a third PP O₂ prior to permitting transfer of the substrate into the first processing module.

In other features, the first processing module is configured to perform a thin film deposition process using a precursor vapor that is sensitive to reactions with oxidizers.

In other features, the one or more pumps include a turbo pump and a water pump. In other features, the one or more pumps include a turbo pump and not a water pump. In other features, the one or more pumps include a water pump. In other features, the one or more pumps include only a single pump.

In other features, the one or more pumps include two or more pumps for pumping gases from the vacuum transfer module. In other features, the inert gas includes argon gas.

In other features, the one or more pumps include: a turbo pump; and an inline water pump connected in series between the vacuum transfer module and the turbo pump. One of the valves is connected in series between the inline water pump and the turbo pump.

In other features, the substrate processing tool further includes an adapter connected to the vacuum transfer module. The one or more pumps include: a turbo pump; and an inline water pump connected in series between the vacuum transfer module and the turbo pump; and one of the valves is connected in series between the adapter and the inline water pump.

In other features, a substrate processing tool is disclosed and includes: a first processing module; a vacuum transfer module connected to the first processing module; one or more pumps; a backfill source; and one or more controllers. The one or more controllers are configured to: control the one or more pumps to reduce a PP O₂ in the vacuum transfer module from a first PP O₂ to a second PP O₂ and then backfill the vacuum transfer module with an inert gas to a third PP O₂ prior to permitting transfer of a substrate into the first processing module; subsequent to backfilling the vacuum transfer module, cause transfer of the substrate from the vacuum transfer module to the first processing module; and cause the first processing module to process the substrate.

In other features, the substrate processing tool further includes valves connected to the one or more pumps and the backfill source. The one or more controllers are configured to control the one or more pumps and the valves to reduce the PP O₂ in the vacuum transfer module from the first PP O₂ to the second PP O₂ and then backfill the vacuum transfer module with the inert gas to the third PP O₂ prior to permitting transfer of the substrate into the first processing module.

In other features, a substrate processing tool is disclosed and includes: a first processing module; a vacuum transfer module connected to the first processing module; one or more pumps; a backfill source; and one or more controllers. The one or more controllers are configured to: control the one or more pumps to reduce a PP H₂O in the vacuum transfer module from a first PP H₂O to a second PP H₂O and then backfill the vacuum transfer module with an inert gas to a third PP H₂O prior to permitting transfer of a substrate into the first processing module; subsequent to backfilling the vacuum transfer module, cause transfer of the substrate from the vacuum transfer module to the first processing module; and cause the first processing module to process the substrate.

In other features, the substrate processing tool further includes valves connected to the one or more pumps and the backfill source. One or more controllers are configured to control the one or more pumps and the valves to reduce the PP H₂O in the vacuum transfer module from the first PP H₂O to the second PP H₂O and then backfill the vacuum transfer module with the inert gas to the third PP H₂O prior to permitting transfer of the substrate into the first processing module.

In other features, the one or more controllers is configured to adjust the PP H₂O in the vacuum transfer module based on a chamber pressure of the vacuum transfer module.

In other features, a method of operating a substrate processing tool is disclosed and includes: receiving a substrate at a vacuum transfer module, where the vacuum transfer module is connected to a first processing module and a second processing module; pumping, via one or more pumps, the vacuum transfer module down from a first chamber pressure to a second chamber pressure; backfilling the vacuum transfer module with an inert gas from the second chamber pressure to a third chamber pressure; transferring the substrate from the vacuum transfer module to the first processing module; performing a first type of substrate process on the substrate in the first processing module; subsequent to processing the substrate in the first processing module, transferring the substrate from the first processing module back to the vacuum transfer module; backfilling the vacuum transfer module with the inert gas from the third chamber pressure to the first chamber pressure; and transferring the substrate from the vacuum transfer module to the second processing module.

In other features, the method further includes maintaining the third chamber pressure in the vacuum transfer module while processing the substrate in the first processing module.

In other features, the method further includes: pumping the vacuum transfer module down to the second chamber pressure includes pumping down the vacuum transfer module from a first PP O₂ to a second PP O₂; backfilling the vacuum transfer module with the inert gas to the third chamber pressure includes backing filling the vacuum transfer module from the second PP O₂ to a third PP O₂; and backfilling the vacuum transfer module with the inert gas to the first chamber pressure includes backfilling the vacuum transfer module from the third PP O₂ to the first PP O₂.

In other features, the one or more pumps include a turbo pump and a water pump. The second PP O₂ is provided by at least one of reducing a chamber pressure of the vacuum transfer module to a pressure less than 3e−5 T or running the turbo pump and the water pump for a predetermined period of time to draw gases from the vacuum transfer module.

In other features, the method further includes: pumping the vacuum transfer module down to the second chamber pressure includes pumping down the vacuum transfer module from a first PP H₂O to a second PP H₂O; backfilling the vacuum transfer module with the inert gas to the third chamber pressure includes backing filling the vacuum transfer module from the second PP H₂O to a third PP H₂O; and backfilling the vacuum transfer module with the inert gas to the first chamber pressure includes backfilling the vacuum transfer module from the third PP H₂O to the first PP H₂O.

In other features, the one or more pumps include a turbo pump and a water pump. The second PP H₂O is provided by at least one of reducing a chamber pressure of the vacuum transfer module to a pressure less than 3e−5 T or running the turbo pump and the water pump for a predetermined period of time to draw gases from the vacuum transfer module.

In other features, a substrate processing tool is disclosed and includes: a vacuum transfer module configured to transfer substrates between a first processing module and at least one of a buffer and a second processing module; one or more pumps; a pendulum valve configured to control flow of fluids from the vacuum transfer module to the one or more pumps; a backfill source; a first purge valve configured to control flow of fluids from the backfill source to the vacuum transfer module; a water pump configured to chill a cold plate, the cold plate being arranged to draw water from within the vacuum transfer module; and one or more controllers configured to control the one or more pumps, the pendulum valve, the first purge valve and the water pump to regenerate the cold plate.

In other features, the one or more controllers is configured to deactivate the water pump and maintain the pendulum valve and the first purge valve in open states while running the one or more pumps to heat up the cold plate and remove water from the cold plate and the vacuum transfer module.

In other features, the one or more controllers is configured to determine when regeneration of the cold plate is completed and if the vacuum transfer module is to be opened, and subsequent to completing regeneration of the cold plate either (i) close the pendulum valve and the first purge valve in response to determining the vacuum transfer module is to be opened, or (ii) maintain the pendulum valve and the first purge valve in an open state in response to determining the vacuum transfer module is not to be opened.

In other features, the one or more controllers is configured to determine the vacuum transfer module is not to be opened, and in response, operate the pendulum valve in an open controlling mode.

In other features, the substrate processing tool further includes a vent valve. The one or more controllers is configured to determine that the vacuum transfer module is to be opened, and in response, open the vent valve to increase pressure within the vacuum transfer module prior to the vacuum transfer module being opened. In other features, the cold plate is disposed in the vacuum transfer module.

In other features, the substrate processing tool further includes: a water pump isolation chamber attached to the vacuum transfer module; and an isolation valve configured to separate an interior of the vacuum transfer module from an interior of the water pump isolation chamber. The cold plate is disposed within the water pump isolation chamber.

In other features, the one or more controllers is configured to open the isolation valve during use of the cold plate to draw water from within the vacuum transfer module. In other features, the one or more controllers is configured to close the isolation valve during regeneration of the cold plate.

In other features, the substrate processing tool further includes a water pump roughing valve and a second purge valve. The one or more controllers is configured to open the water pump roughing valve and the second purge valve during regeneration of the cold plate. In other features, the one or more controllers is configured to close the isolation valve when the vacuum transfer module is opened to the atmosphere.

In other features, the substrate processing tool further includes a water pump roughing valve and a second purge valve. The one or more controllers is configured to open the water pump roughing valve and the second purge valve when the vacuum transfer module is opened to the atmosphere to maintain the water pump isolation chamber at a pressure below atmospheric pressure.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example substrate processing tool including a single roughing pump and configured to provide a low partial pressure of water vapor (PP H₂O) and low PP of oxygen (O₂) environment in accordance with the present disclosure;

FIG. 2 is a graph including PP H₂O plots for respectively pump down with a water pump and pump down without a water pump;

FIG. 3 illustrates a selective PP H₂O and O₂ process implemented for substrate transfers between different processing modules in accordance with some embodiments of the present disclosure;

FIG. 4 is a graph including a chamber pressure plot in accordance with some embodiments of the present disclosure;

FIG. 5 is a functional block diagram of another example substrate processing tool including two roughing pumps and configured to provide a low partial pressure of water vapor (PP H₂O) and low PP of oxygen (O₂) environment in accordance with the present disclosure;

FIG. 6 is a functional block diagram of a portion of a substrate processing tool including an inline water pump disposed between a vacuum transfer chamber and a turbo pump in accordance with some embodiments of the present disclosure;

FIG. 7 is a functional block diagram of a portion of a substrate processing tool including an inline water pump disposed between a valve and a turbo pump in accordance with some embodiments of the present disclosure;

FIG. 8 is a first table of operations performed prior to and during water pump regeneration in accordance with some embodiments of the present disclosure;

FIG. 9 illustrates a method of performing water pump regeneration without use of a water pump isolation chamber and isolation valve in accordance with some embodiments of the present disclosure;

FIG. 10 is a functional block diagram of an example substrate processing tool including a water pump isolation chamber with a water pump isolation valve in accordance with some embodiments of the present disclosure;

FIG. 11 is a second table including operations performed prior to, during and subsequent to water pump regeneration using the water pump isolation valve of FIG. 10; and

FIGS. 12A-12B (collectively FIG. 12) illustrates a method of performing water pump regeneration with use of a water pump isolation valve in accordance with some embodiments of the present disclosure.

In the drawings, reference numbers may be reused to identify similar and/or identical elements.

### DETAILED DESCRIPTION

A substrate processing tool may include a vacuum transfer module (VTM) connected to multiple processing modules. Each of the processing modules may perform a same or different types of substrate process, such as a deposition or etch process. In some instances, the VTM is held at a constant pressure to allow transfer of substrates between processing modules of the same tool.

Etch and deposition process modules operate at a variety of different processing and substrate transfer pressures. By coupling multiple process modules onto a single VTM, substrates are able to be transferred between process modules that are performing sequential processes. For example, a first deposition process may be performed on a substrate in a first processing module and then transferred via a VTM to a second processing module at which a second deposition process may be performed. This is different than transferring a substrate between processing modules of different separate dedicated tools, where a substrate is removed from a vacuum environment of a first tool, exposed to an atmospheric environment, transported via a container to a next tool, and then transferred within a vacuum environment of the next tool to a next processing module. This exposes the substrate to different environments and can result in surface damage to the substrate. The direct transfer from the first process module through a VTM to the second process module does not expose the substrate to the atmospheric environment and reduces queue time (or time between sequential processes). The direct transfer between processing modules connected to the same VTM also reduces time the substrate is exposed to the environment within the VTM and as a result reduces potential contamination of and/or damage to surfaces of the substrate.

Integration of multiple processing modules in a single tool and on the same VTM creates technical challenges. As an example, there can be issues associated with switching between different pressures within a VTM to accommodate different processing modules and associated chamber pressures. In addition, it can be difficult to schedule transfers of substrates between processing modules and processing of the substrates at the processing modules due to different lengths of processing operations performed.

In certain applications, processes are performed that result in substrate surfaces that are sensitive to H₂O and O₂. As an example, a substrate may be pre-cleaned in a first processing module and as a result have surfaces that are highly sensitive to H₂O and O₂. The substrate may then need to be transferred to a deposition processing module. Due to the highly sensitive surfaces, the substrate needs to be transferred in an environment that has low levels of H₂O and O₂. In addition, substrate sequencing needs to be accomplished quickly to achieve tool substrate throughput with minimal costs.

Some substrate processes that are highly sensitive to presence of H₂O and O₂ can be performed on tools that utilize VTMs capable of being operated at a high vacuum level (1e−7 Torr (T)). A cryogenic water pump may be used in combination with a turbo pump to reduce pressure in a VTM to the high vacuum level. In some embodiments, process modules connected to the VTM are designed for high vacuum pressures and the transfer of substrates between the processing modules are relatively simple with respect to setting the transfer pressures.

Some emerging applications require use of the same or different types of process modules operating at elevated and differing vacuum levels. The different types of processing modules perform different types of processes, such as clean, deposition and etch processes. As an example, sequential processes may require VTM transfer pressures that range between 20 milli-Torr (mT) and 90 T. In some instances, the tools of these applications may require throughput of at least 25 substrates per hour. This throughput is provided as an example and may be less than 25 substrates per hour. Some the tools may have two or more of each type of processing module (e.g., two clean processing modules, two deposition processing modules and two etch processing modules). In some instances, more than two of each type of processing module may be included when throughput is not balanced across the different types of processing modules or for redundancy to improve tool throughput.

The examples set forth herein include substrate processing tools that selectively provide a low partial pressure (PP) of water and low PP O₂ environment for transferring substrates between processing modules. In some embodiments, this environment is provided in VTMs, where each of the VTMs is connected to multiple processing modules. Substrates are able to be quickly transferred between processing modules of the same or different types performing the same and/or different type of substrate processing. In an example, a substrate can be transferred from a pre-clean module to a deposition module in a clean environment with a PP H₂O of less than 4e−6 T and PP O₂ of less than 1e−5 T to prevent damage to cleaned substrate surfaces.

A substrate transfer chamber (in some embodiments, referred to as a VTM) in accordance with some embodiments of the present disclosure is connected/coupled to multiple processing modules, which operate over a large range of pressures. As a result, a large range of associated VTM transfer pressures is required to accommodate different operating conditions. The VTM tool is configured to maintain low H₂O and O₂ levels in selective ranges in the VTM during transfers between the processing modules. For example, the VTM tool is capable of maintaining PP H₂O levels in, for example, a 200 T to 2.05e−7 T range and switching between different pressure levels within this range.

Some of the examples include use of a water pump to aid in pumping out water vapor and to reduce time to achieve target pressure levels within a VTM. Atmospheric gas such as nitrogen (N₂), O₂, H₂O (water vapor), and others can continually leak into a VTM through various O-ring seals. In some embodiments, these gases must be removed, especially the ones that can create substrate surface defects during transfer. Water vapor is often the dominant gas molecule detected. Water vapor in substrate transfer chamber is difficult to remove since it tends to stick to chamber walls and randomly releases (referred to as outgassing). In some instances, heating the chamber can reduce this outgassing effect, but causes other associated technical challenges.

Some of the examples disclosed herein include using a turbomolecular (or turbo) pump and water pump (e.g., a cryogenic water pump) to remove certain gases and reduce the overall pressure within a VTM. In some embodiments, an overall chamber pressure of the VTM can quickly be brought down to 5e−6 T and then backfilled with one or more inert gases (e.g., argon gas (Ar₂)) to a specific elevated transfer pressure. This creates a low H₂O and O₂ content environment for a substrate to be transferred between processing modules of a single tool. Backfilling may include one or more inert gases, such as Argon, Nitrogen and/or other suitable inert gases, depending on the application of use. A cryogenic water pump removes water vapor from a chamber more efficiently than the turbo pump. Although the turbo pump is capable of removing water vapor, the turbo pump may be primarily used to remove gases other than water vapor. The turbo pump may also be used to remove an inert gas used to backfill the VTM.

By providing a tool that is configured to selectively and controllably create a low PP H₂O and O₂ environment for certain substrate transfers, damage to substrate surfaces is reduced and transfers between processing modules are performed with minimal impact on throughput. The stated selectivity allows process modules with varying transfer pressures preference to be integrated into a single tool for processing substrates in different types of processing modules.

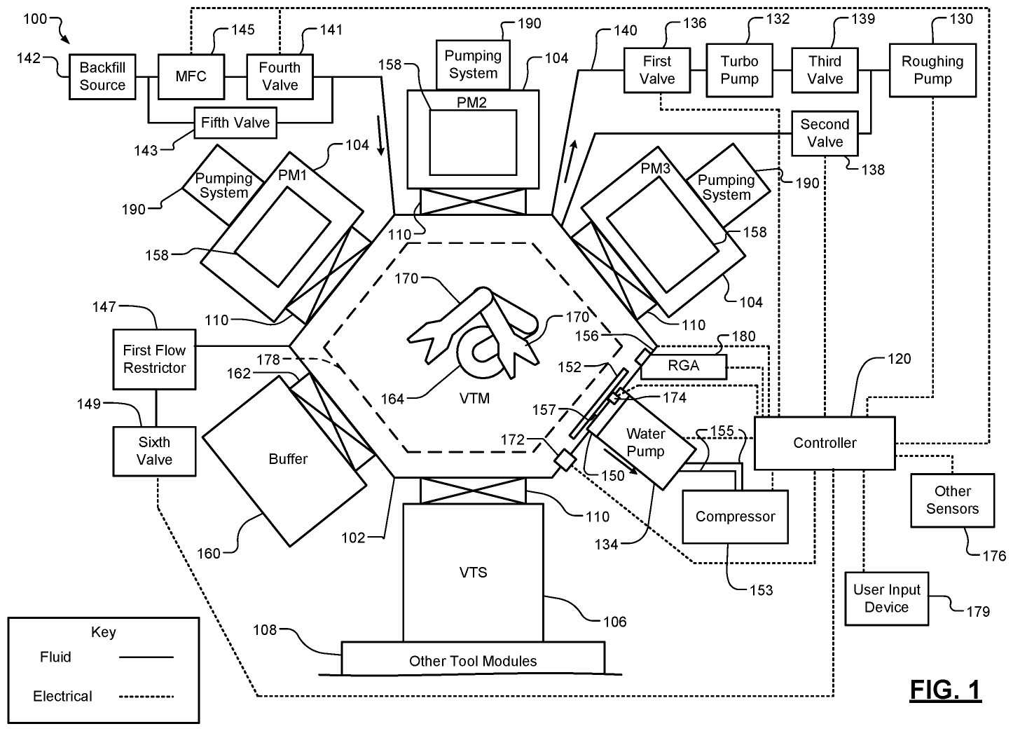

FIG. 1 shows a substrate processing tool 100 configured to provide a low PP H₂O and O₂ environment according to some embodiments of the present disclosure. The substrate processing tool 100 includes a VTM 102, multiple processing modules (PMs) 104, a vacuum transfer system (VTS) 106, and other tool modules 108. The VTM 102 is connected to the PMs 104 and the VTS 106 via doors 110. Although not shown, opening and closing the doors 110 may be controlled by a controller 120. In some embodiments, the controller 120 also controls pressure within the VTM 102 and supply of one or more gases to the VTM 102.

In some embodiments, the controller 120 may control the pressure within the VTM 102 via one or more pumps (e.g., one or more of a roughing pump 130, a turbo pump 132, and a water pump 134) and multiple valves (e.g., a first valve 136, a second valve 138 and a third valve 139). In the example shown, the turbo pump 132, the roughing pump 130 and the first valves 136, 139 are connected in series. The first valve 136 is connected to the VTM 102 via a line (or conduit) 140 and to an input of the turbo pump 132. The second valve 138 is connected at a first end to the VTM 102 and is connected at a second end to an output of the third valve 139 and an input of the roughing pump 130. The roughing pump 130 may draw gas from (i) the turbo pump 132, and/or (ii) through the valves 136, 138, 139 via respective lines (or conduits).

In some embodiments, the first valve 136 may be referred to as a pendulum valve. The second valve 138 may be referred to as a throttle valve. The third valve 139 may be referred to as an isolation valve. The isolation valve 139 may be closed when the chamber pressure within the VTM 102 is greater than or equal to a predetermined pressure (e.g., 90 T). When the turbo pump is spinning at a high revolutions-per-minute (RPM) (e.g., 20,000 RPM) and the pendulum valve 136 is closed, the isolation valve 139 is closed to prevent a high back pressure on a backside (or output) of the turbo pump 132. This prevents damage to the turbo pump 132.

The controller 120 may further control pressure by backfilling of the VTM 102. In one embodiment, this is accomplished by adjusting flow of a backfill gas (e.g., one or more inert gases). In one embodiment, argon gas is used as the backfill gas. As shown, the controller 120 may control operation of a mass flow controller (MFC) 145, a fourth valve 141, and a fifth valve 143. The fourth valve 141 is connected in series between the VTM 102 and a backfill source 142. The fifth valve 143 is connected in parallel with the MFC 145 and the fourth valve 141. The backfill source 142 may include for example one or more valves, one or more gas canisters, etc. and store and/or supply one or more gases, such as one or more inert gases. The MFC 145 and the valve 141 are used to provide a known quantity of gas to the VTM 102. The fifth valve 143 is used to raise pressure within the VTM 102 quickly. The controller 120 controls opening states of the valves 141, 143 based on how quick a chamber pressure within the VTM 102 is to be increased. In one embodiment, a universal pressure controller is used to control back pressure through the valve 141.

In one embodiment, the controller 120 controls the MFC 145 and the valve 141 to provide a continuous purge gas (e.g., one or more inert gases, such as Ar) to the VTM 102. The purge flow dilutes any contaminants within the VTM 102 including diluting water vapor and/or other gases, which may seep into the VTM 102 as a result of outgassing from walls of the VTM 102 and/or leaks at seals of the VTM 102. This may occur, for example, during and/or after transitioning a chamber pressure within the VTM 102 from a first chamber pressure (e.g., 20-40 milli-Torr (mT)), associated with the transfer of a substrate into and out of a first processing module, to a second pressure (e.g., 12 T), associated with the transfer of the substrate into and out of a second processing module. In an embodiment, the valve 143 is closed during the transition from the first chamber pressure to the second chamber pressure.

In one embodiment, the valve 143 is closed when the pressure within the VTM 102 is close to or within a predetermined range of the second chamber pressure. In an embodiment, backfill gas is turned on to provide a fixed purge flow via the MFC 145 and the valve 141 while the valves 136, 138 are throttled to control the chamber pressure within the VTM 102. This may occur during the stated transfers of a substrate and is done to prevent backflow of residual PM process gases into the VTM 102 from the PM chambers. The pressure of a PM is lower than a pressure of the VTM 102 during a wafer transfer between the PM and the VTM 102.

The substrate processing system 100 may further include a first flow restrictor 147 and a sixth valve 149. The first flow restrictor restricts flow of air to the VTM 102 through the sixth valve 149. The sixth valve 149 is a vent valve that that increases pressure within the VTM 102 prior to the VTM 102 being opened.

The controller 120 may control states of the valves 136, 138, 139, 141, 143, 149 between fully open and fully closed states. The controller 120 may throttle and/or adjust opening states (e.g., adjust positions of throttle plates) of the valves 136, 138, 139, 141, 143, 149. As an example, the controller 120 may adjust an open state of the first valve 136 to maintain a set target pressure within the VTM 102. This may include regulating flow of gas drawn from the VTM 102. The valves 136, 138, 139, 141, 143, 149 may be adjusted to partially open states, such that the valves 136, 138, 139, 141, 143, 149 are not fully open or fully closed. One or more of the valves 136, 138, 139, 141, 143 may be self-sealing and used for isolation purposes. For example, the valves 136, 138, 139 may be self-sealing valves (or include seals) such that the valves 136, 138, 139 are able to isolate the roughing pump 130 from the VTM 102. Although the valves 136, 138 are shown as being coupled to a side wall of the VTM 102, the valves 136, 138 may be connected to a bottom wall of the VTM 102.

The water pump 134 may be a cryogenic water pump that is configured to pump water vapor and is coupled to the VTM 102. As shown, the water pump 134 is connected to a side wall of the VTM 102, but may be connected to, for example, a bottom wall of the VTM 102. In some embodiments, the water pump 134 includes a sealing plate 150 that is coupled to a cold plate 152 via a coupler (sometimes referred to as a cold head) 157. The cold plate 152 is not attached to an inside wall 156 of the VTM 102, but rather is suspended in the vacuum environment of the VTM 102 by the sealing plate 150. Gaps exist between the cold plate 152 and adjacent surfaces of the VTM 102 to minimize heat transfer from the cold plate 152.

The cold plate 152 increases surface area of the sealing plate 150 and draws heat and water vapor from within the VTM 102. The water pump 134 may maintain the cold plate 152 at, for example, 12° Kelvin (K). The water pump 134 draws water vapor, not other gases, such as N₂, O₂, and Ar₂. The water pump 134 has a direct line-of-sight with an interior of the VTM 102 for operating efficiency purposes in molecular flow regime pressures. In some embodiments, the water pump 134 is provided compressed helium (He) via a compressor 153 to cool the plate 152. The compressor 153 is connected to the water pump 134 with supply and return lines 155 and may be controlled by the controller 120.

Each of the PMs 104 may be configured to perform one or more respective processes on a substrate. In one embodiment, the PMs 104 perform respectively clean, deposition and etch processes. Although a single PM 104 is shown for each type of process, namely one PM for clean, one PM for deposition and one PM for etch, more than one PM may be connected to the VTM 102 for each type of process. As an example, the PMs 104 may include a first PM PM1, a second PM PM2 and a third PM PM3. PM1 may perform a pre-clean process. PM2 may perform a deposition process. PM3 may perform an etch process. The PMs 104 include respective processing chambers 158.

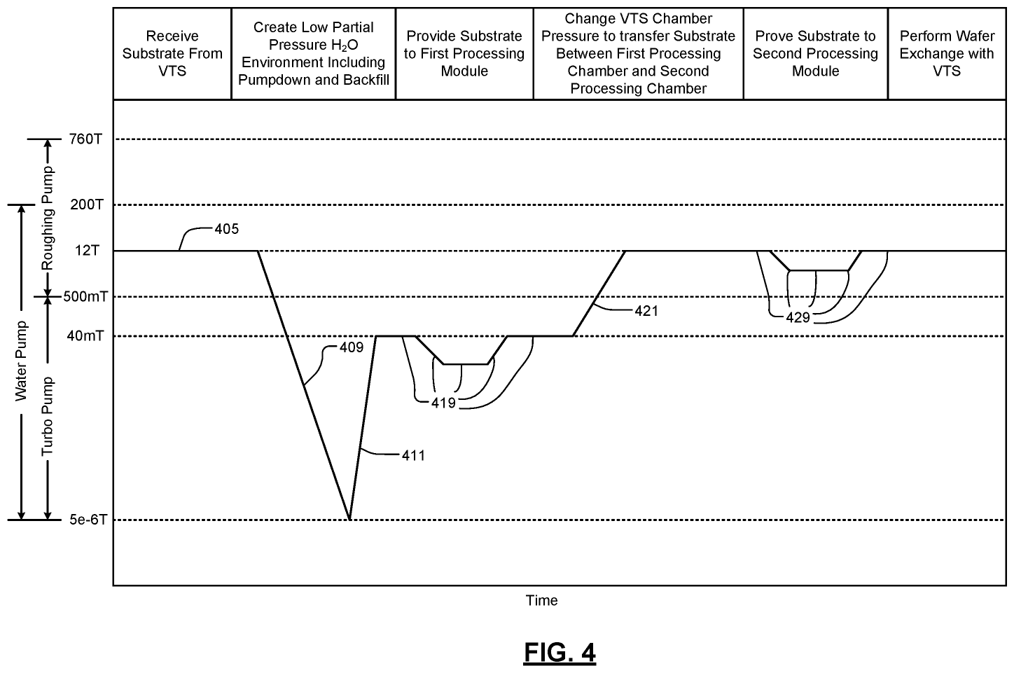

A buffer 160 may be attached to the VTM 102 and store substrates. As an example, when there is a timing conflict with the PMs 104 and/or operation of the VTS 106, one or more substrates may be stored in and/or removed from the buffer 160. A substrate may be temporarily stored in the buffer 160: between processing operations of the PMs 104; subsequent to receiving the substrates from the VTS 106; and/or subsequent to completion of processing the substrate and prior to being returned to the VTS 106. Access to the buffer 160 may be through a door 162 that is controlled by the controller 120. In one embodiment, a door to the buffer 160 is not included and the buffer 160 is open to the interior of the VTM 102. The buffer 160 may be used during the method of FIG. 4, for example, when moving substrates between the VTM 102 and the VTS 106, between the VTM 102 and the PMs 104, and/or between the PMs 104 via the VTM 102.

A transfer robot 164 is located within the VTM 102 and may be used to move substrates to and from the VTS 106, the PMs 104, and the buffer 160. The transfer robots 164 may have different end effector and corresponding arm configurations. The transfer robot 164 may include one or more arms and one or more end effectors. In the example shown, the transfer robot 164 includes two end effectors 170. The end effectors 170 may be on a same arm or on different arms. The end effectors 170 may be at different angles relative to each other. As an example, the first end effector may oppose the second end effector or be 180° away from the second end effector.

The VTS 106 and/or the other tool modules 108 may include one or more additional robots arranged to transfer substrates (i) from loading stations to airlocks and/or load locks, and (ii) from the load locks to PMs and/or the VTS 106. The other tool modules 108 may include, for example, other PMs, an atmosphere-to-vacuum (ATV) transfer module, an equipment front end module (EFEM), a degassing module, a load lock module, airlocks, etc.

In the example shown in FIG. 1, the VTM 102 has a hexagonal arrangement with six sidewalls, but in some embodiment, VTM 102 may have a different number of sidewalls. The size of the VTM 102 may be changed to better accommodate a different number of PMs. The PMs 104, water pump 134 and the buffer 160 are shown in a particular arrangement azimuthally around the VTM 102. The PMs 104, water pump 134 and the buffer 160 may be in a different arrangement.

A pressure sensor 172 may be coupled to the VTM 102 and detect chamber pressure within the VTM 102. The coupling of the pressure sensor 172 to the VTM 102 may be direct or indirect. The controller 120 may adjust operation of the pumps 130, 132, 134, the MFC 145 and/or states of the valves 136, 138, 139, 141, 143 based on an output of the pressure sensor 172. In another embodiment, the pumps 130, 132, 134, the MFC 145 and/or valves 136, 138, 139, 141, 143 are controlled via a timing schedule. This control may be provided based on the output of the sensor 172 or independent of the output of the sensor 172. In one embodiment, one or more of the pumps 130, 132, 134 are maintained in ON states and running and a chamber pressure within the VTM 102 is adjusted via the MFC 145 and the valves 136, 138, 139, 141, 143. In one embodiment, for example, the water pump 134 is maintained in an ON state and running. As another example, at least one of the roughing pump 130 and the turbo pump 132 is maintained in an ON state and running.

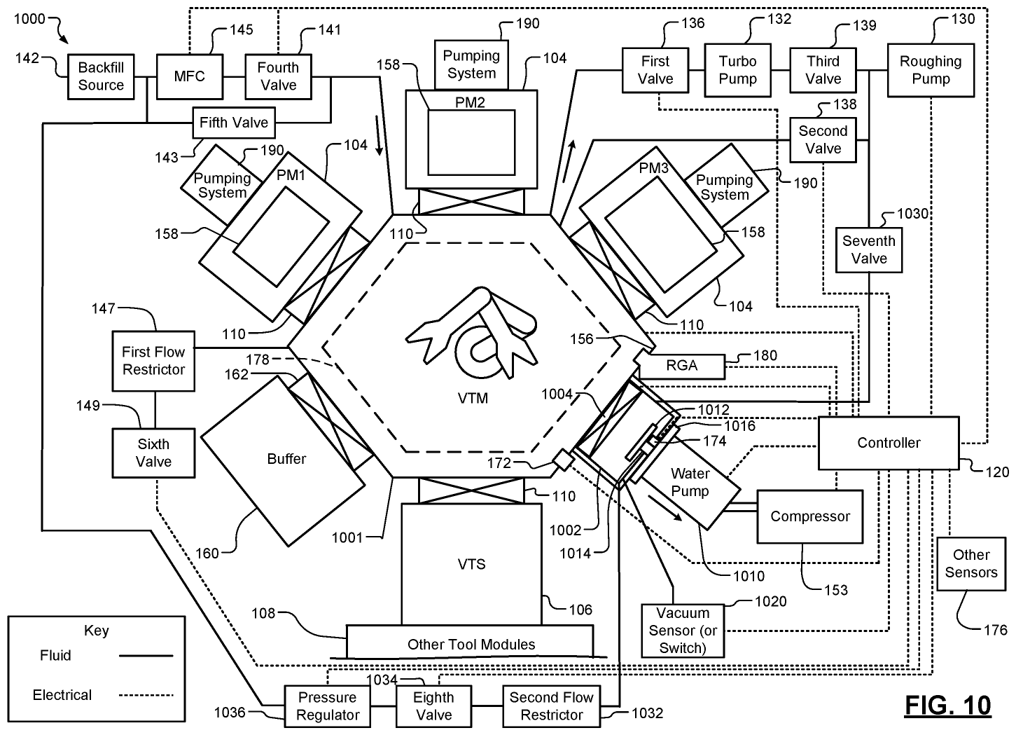

A temperature sensor 174 and/or other sensors 176, such as a door sensors, may also be included. The temperature sensor 174 may be used to detect a temperature of the cold plate 152 and/or the water pump 134. The door sensors may be used to detect, for example, when a lid (or door) 178 of the VTM 102 is open and closed. This sensed information may be used, for example, during operations performed to regenerate the water pump 134 and thus remove any build up of frozen water on the cold plate 152. An example water pump regeneration method is shown in FIG. 9. A user input device 179 may be included to receive an input to activate water pump regeneration. As an example, the user input device 179 may be a touch pad, a keyboard, a mouse, a touchscreen, a display, etc. The water pump 134 may alternatively be regenerated automatically as described below.

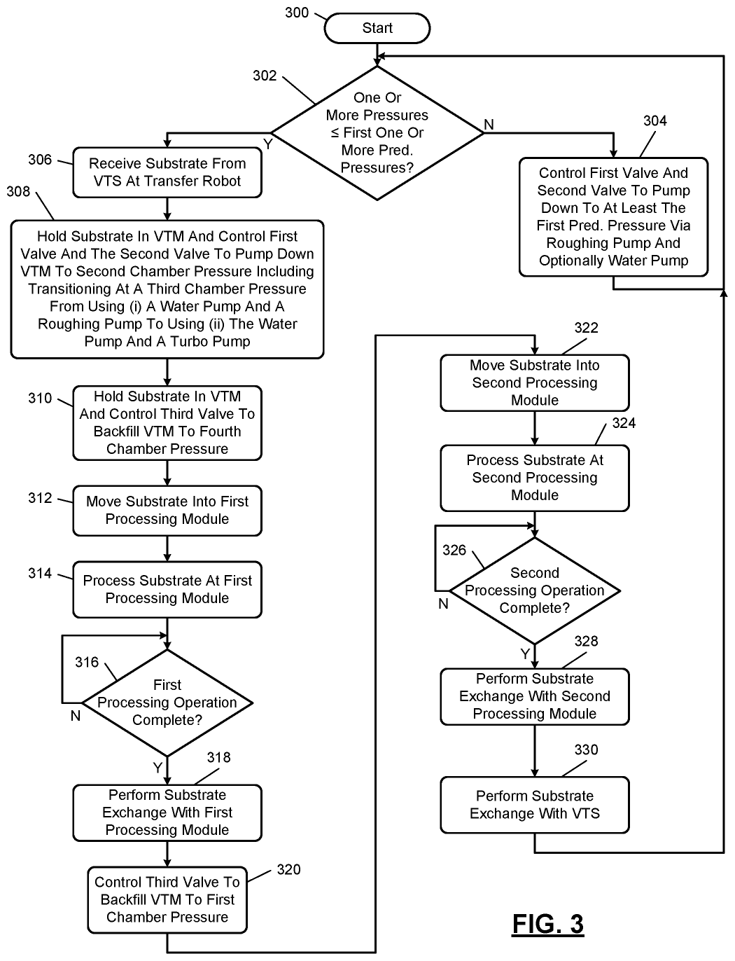

In some embodiments, the substrate processing tool 100 may include a residual gas analyzer (RGA) 180. The RGA 180 samples a gas mixture within the VTM 102 and determines the elements of the gas mixture, the ratios of the elements (or gases). The RGA 180 and/or the controller 120 may then determine the PP H₂O and/or the PP O₂ based on the determined ratios. The RGA system may determine gas molecules by volume and/or atomic gas units of the gas mixture. The RGA system may include a mass spectrometer and one or more pressure sensors, such as manometers) for measuring gas pressures. The RGA system may be used to measure traces of impurities. The RGA system may measure pressure by sensing weight of each atom as it passes through a quadrupole. The RGA system may be used to validate that certain partial pressures exist prior to performing a substrate transfer to a processing module, between processing modules, and/or from a processing module. This validation may be performed by the RGA system and/or the controller 120 prior to performing, for examples, the transfers described below as being performed during the method of FIG. 3. As an example, the sequencing of operations and transfers performed during the method of FIG. 3 may be based on the determined PP H₂O and/or the PP O₂. When the PP H₂O and/or the PP O₂ are within predetermined ranges for the respective transfers, the transfers are performed. Although FIG. 3 is primarily described with respect to chamber pressures, the operations may be performed based on the PP H₂O and/or the PP O₂ alone or in combination with the determined chamber pressures.

Each of the PMs 104 may have a respective pumping system 190. The pumping systems 190 may each include one or more pumps for pumping down pressures within the chambers 158. The pumping systems 190 may include one or more controllers for control pump down of the chambers 158. The pumping systems 190 may be in communication with the controller 120 and/or an intermediate interface (e.g., a user interface). The pumping systems 190 may be used to maintain pressures within the chambers 158 at pressures that are lower than chamber pressures within the VTM 102. This prevents gases within the chambers 158 from passing into the VTM 102 and aids in maintaining a clean environment within the VTM 102.

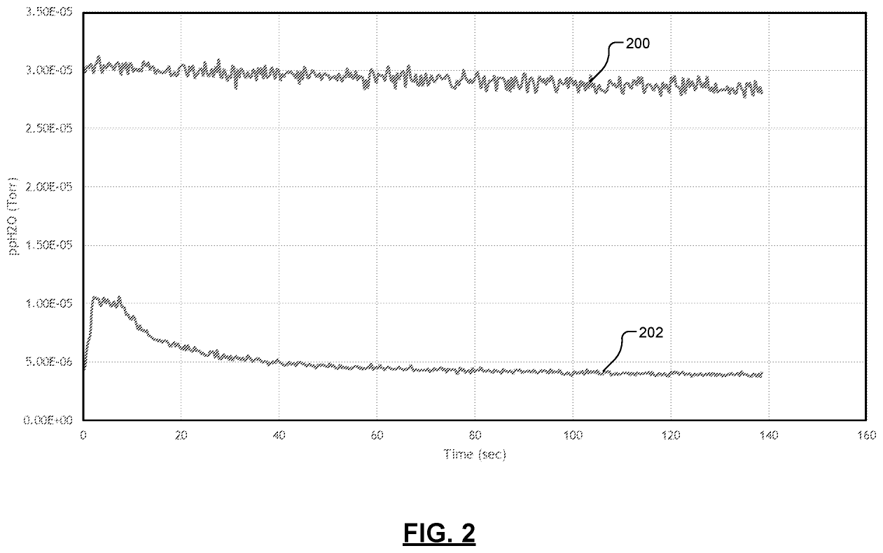

FIG. 2 shows a graph including (i) a PP H₂O plot 200 for pump down with a turbo pump and without use of a water pump, and (ii) a PP H₂O plot 202 for pump down with the turbo pump and a water pump. The turbo pump and the water pump may refer respectively to the pumps 132, 134 of FIG. 1. The use of the water pump 134 allows for a quicker reduction in pressure and a reduction to a lower pressure (or higher vacuum level). As can be seen from the plots 200, 202 and Table 1, a lower PP H₂O can be obtained using the water pump 134 than when not using the water pump 134. This is shown in col. 3 of Table 1. Col. 2 of Table 1 shows that the base pressure or minimum pressure when using the water pump 134 is also lower than when not using the water pump 134. The base pressure refers to the steady state total pressure of gases within the chamber (or VTM) when no backfill/purge gas is being delivered to the VTM 102, whereas the PP H₂O refers to the notional pressure of water vapor in that chamber. The base pressure is established when all gas delivery is shut off and the VTM 102 is pumping down for an extended period of time. The base pressure may refer to a lowest pressure the VTM 102 will pump down to due to leakage and outgassing effects. Col. 4 of Table 1 shows that by using the water pump 134, the time to pump down from a chamber pressure of 12T to a chamber pressure of less than 5e−06 T within the corresponding chamber (or VTM) is substantially less than when not using the water pump 134.

TABLE 1
Example PP H₂O and Pump down Times
for Different Pump Configurations

| | Base | | Pump Down From 12 T |
|---|---|---|---|
| Active Pumps | Pressure | PP H₂O | to less than 5e−06 T |
| Turbo Pump | 9.7e−07 T | 2.8e−05 T | 113 s |
| Turbo Pump and | 2.05e−07 T | 3.9e−06 T | 74 s |
| Water Pump | | | |

FIG. 3 shows a selective PP H₂O and O₂ control process implemented for substrate transfers between different PMs according to some embodiments of the present disclosure. The method provides dynamic pressure control using multiple pumps, MFC and valves. The PMs may be at different pressures for the same or different types of substrate processing operations performed in the PMs. Although described with respect to chamber pressures, the PP H₂O, and the PP O₂, the PP of other gases are also adjusted due to operation of a roughing pump and a turbo pump.

The method may begin at 300 and the operations may be iteratively performed for multiple substrates. The operations may be performed by the controller 120 of FIG. 1. Although the following operations are primarily described with respect to chamber pressures being adjusted to be within certain ranges and/or having certain values, due to the pumping and backfilling performed, the PP H₂O and the PP O₂ are also likewise adjusted (decreased or increased). The PP H₂O and the PP O₂ are less than the corresponding chamber pressures and may be substantially less than the chamber pressures, especially due to the backfilling and purging operations performed. In some embodiments, the PP H₂O and the PP O₂ are small fractions of the total amount of gas within the VTM 102.

At 302, the controller 120 may determine whether one or more pressures within the VTM 102 are less than or equal to a respective first one or more predetermined pressures. The one or more pressures may include a chamber pressure, a PP H₂O and/or a PP O₂. In one embodiment, this operation is performed based only on the chamber pressure. In another embodiment, this operation is performed based on the chamber pressure, the PP H₂O, and/or the PP O₂. If the pressure(s) are not less than or equal to the first one or more predetermined pressures, operation 304 may be performed, otherwise operation 306 may be performed.

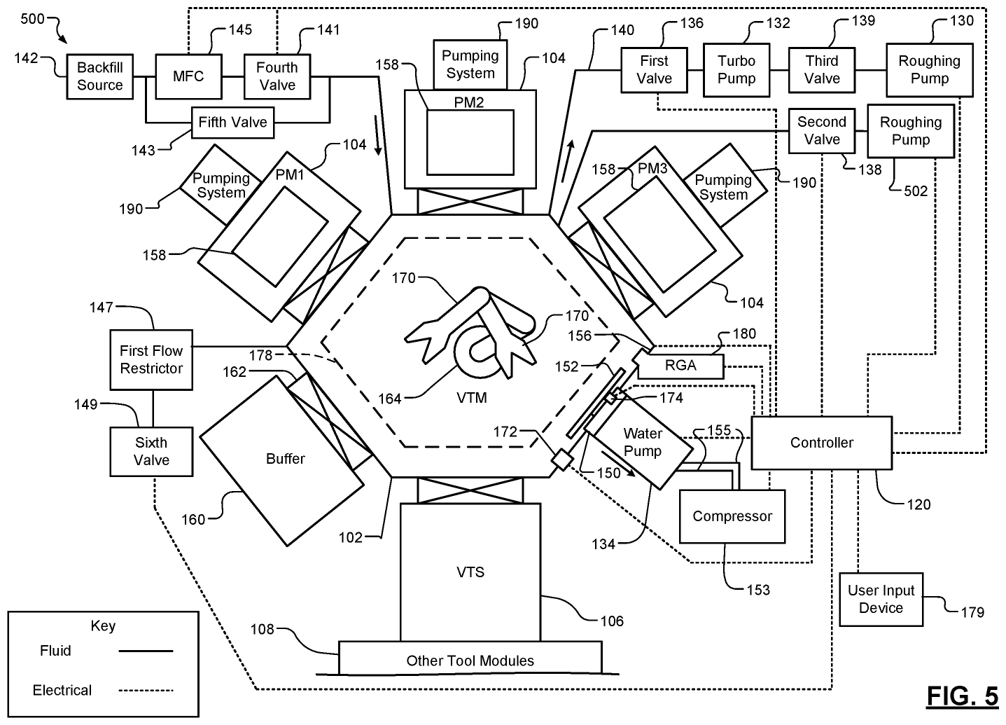

At 304, the controller 120 may control the state of the first valve 136, the second valve 138, one or more roughing pumps (e.g., one or more of roughing pumps 130, 502 of FIGS. 1, 5) and/or the water pump 134 to pump down to at least the first one or more pressures (e.g., a first chamber pressure, a first PP H₂O, and a first PP O₂). This may be accomplished via the one or more roughing pumps and optionally the water pump 134. The second valve 138 is in an open state during this operation. As an example, the roughing pump(s) may be used to pump down to the first chamber pressure (e.g., to about 10-14 T), the first PP H₂O, and/or the first PP O₂. In one embodiment, the first chamber pressure is pumped down or adjusted to 12 T. The first chamber pressure is represented by segment 405 in FIG. 4. FIG. 4 shows an example chamber pressure plot including chamber pressures within the VTM 102 versus time. In some embodiments, the water pump 134 may be used independently or in combination with the turbo pump and/or roughing pump when the chamber pressure within the VTM 102 is less than a predetermined threshold (e.g., less than 200 T). In some embodiments, operation 302 may be performed again, subsequent to operation 304, until the pressure in VTM 102 is equal or less than the predetermined threshold.

At 306, the controller 120 controls the transfer robot 164 in the VTM 102 to retrieve a substrate from the VTS 106. The chamber pressure within the VTM 102 may remain at the first chamber pressure during this operation.

At 308, the controller 120 holds the substrate in the VTM 102 and controls the first valve 136 and the second valve 138 and activates the water pump 134 to pump down the VTM 102 to one or more second chamber pressures (e.g., a second chamber pressure, a second PP H₂O, and a second PP O₂). The second chamber pressure may be less than or equal to 5e−6 T. The second PP H₂O and the second PP O₂ are less than 5e−6 T. In an embodiment, the second chamber pressure is within a predetermined range of 5e−6 T. The predetermined chamber pressure range may be 5e−6 T±5e−7 T. In another embodiment, the second chamber pressure is a pressure provided when operating the pumps 132, 134 for a predetermined period of time (e.g., 74s+5 s) with the first valve 136 in an open state.

In some embodiments, it is desirable to pump down from the first chamber pressure (e.g., about 12 T) to the second chamber pressure (e.g., equal to or less than 5e−6 T) as quickly as possible. As shown in Table 1, embodiments of the present disclosure (e.g., operate turbo and water pump concurrently or sequentially) enable tools to quickly drop the chamber pressure to a desirable chamber pressure (e.g., in about 74s). Reducing the time spent during transition (e.g., 409 and 411 segments in FIG. 4) may increase the tool's total throughput. In some instances, quicker adjustment on chamber pressures may enable the tool to execute recipes that require faster transition time.

In one embodiment, the controller 120 controls operation of the roughing pump(s) and the turbo pump 132 in addition to controlling opening states of the valves 136, 138, 139. In another embodiment, the pumps 130, 132 are maintained in an ON and running state and the controller 120 controls the opening states of one or more of the valves 136, 138, 139 to pump down the VTM 102. In one embodiment, the roughing pump(s) are used to pump down to a third predetermined chamber pressure (e.g., 500 milli-Torr (mT)) and then the turbo pump 132 is used to pump down to the second chamber pressure, as shown in FIG. 4. At the third chamber pressure, the second valve 138 may be closed and/or the roughing pump(s) may be turned OFF. The pump down to the second chamber pressure is shown by segment 409 of FIG. 4.

At 310, the controller 120 holds the substrate in the VTM 102 and controls the third valve 140 to backfill the VTM 102 to a fourth chamber pressure (e.g., 20-90 mT). In one embodiment, the fourth chamber pressure is 20 mT and the corresponding PP H₂O is 7.18E−07 T with a MFC purge flow of Ar of 100 standard cubic centimeter per minute (sccm). In another embodiment the fourth chamber pressure is 90 mT and the corresponding PP H₂O is 1.52E−06 T with a MFC purge flow of Ar of 300 sccm. This operation is represented by line segment 411 of FIG. 4. The backfilling with an inert gas dilutes any remaining contaminant gases, such as H₂O, O₂, N₂, etc. In one embodiment and at the end of operation 310, the PP H₂O is less than 4e−6 T and PP O₂ is less than 1e−5 T.

At 312, the controller 120 moves the substrate in the VTM 102 into the first PM (e.g., PM1). The chamber of the first processing module may be at or near the fourth chamber pressure. In the case of when a first initial wafer is being processed in the substrate processing system (i.e., no substrate in first pre-clean PM), operation 312 may be performed prior to operations 308, 310 and the first substrate is transferred from the VTM 102 and placed into the first PM (e.g., the PM 104) for pre-clean. The PP H₂O in the VTM 102 may not be at a low pressure when the first initial substrate is initially received in the VTM 102. The controller 120 then pumps down the PM in parallel (i.e., concurrently) with pumping down and backfilling the VTM 102. The pumping down and backfilling operations may be similar to the above-described operations 308 and 310. The pumping down and backfilling of the VTM 102 ensures that the PP H₂O in the VTM 102 is at an acceptable level when the substrate is taken out of the pre-clean PM. The initial substrate may then be transferred, for example, to a second processing module while another substrate is transferred into the pre-clean module. As an example, operation 314 may be performed subsequent these transfers for the subsequent (or next) substrate.

At 314, the controller 120 may initiate and control performance of a first substrate process (e.g., a pre-clean process) in the first PM. At 316, the controller 120 determines whether the first processing operation is complete. If yes, operation 318 is performed.

At 318, the controller 120 controls a substrate exchange with the first PM. The transfer robot 164 may remove the substrate (first substrate) from the first PM and replace the first substrate with a next (or second) substrate previously received. This allows the second substrate to be processed in the first PM while the first substrate is processed in a second PM (e.g., PM2). The controller 120 may maintain the fourth chamber pressure while operations 312, 314, 316 and 318 are performed.

Operations 312, 314, 316, 318 are represented by line segments 419 of FIG. 4. During operations 312, 314, 316, 318, a continuous purge flow of the backfill gas may be provided via the MFC 145 and the fourth valve 141 to further dilute any contaminant gases and result in low partial pressures for these gases.

At 320, the controller 120 controls the MFC 145 and the fourth valve 141 to backfill the VTM 102 with inert gas (e.g., argon) to the first chamber pressure (e.g., 10-14 T), represented by segment 421 of FIG. 4. In another embodiment, the first chamber pressure is 10 T and the corresponding first PP H₂O is 2.27E−07 T with a MFC purge flow of Ar of 4500 sccm. In another embodiment, the first chamber pressure is 12 T with a corresponding first PP H₂O, a corresponding first PP O₂, and a MFC purge flow of Ar of 4500 sccm. The backfilling with an inert gas dilutes any remaining contaminant gases, such as H₂O, O₂, N₂, etc. The previous operations create a clean environment and prevent damaging surfaces of the substrate prior to performing the following processing operations on the substrate and allow, for example, subsequent deposition layers to be formed properly. The described pump down and backfill operations may be performed for substrate transfers between PMs performing the same or different types of substrate processing.

At 322, the controller 120 moves the first substrate into the second PM (e.g., a deposition PM). At 324, the controller 120 may control initialization and processing of the first substrate in the second PM. As an example, the second PM may be configured to perform a deposition process in a pressure range near or at the first chamber pressure. At 326, the controller 120 determines whether the second processing operation is complete. If yes, operation 328 is performed.

At 328, the controller 120 controls a substrate exchange with the second PM. The transfer robot 164 may remove the first substrate (or previous substrate) from the second PM and replace the first substrate with the next (or second) substrate, which may have been collected from the first PM. Although a single deposition process is described as being performed, additional deposition processes may be performed and/or other processes such as etch processes may be performed prior to performing operation 330.

Operations 322, 324, 326, 328 are represented by line segments 429 of FIG. 4. During operations 322, 324, 326, 328, a continuous purge flow of the backfill gas may be provided via the MFC 145 and the fourth valve 141 to further dilute any contaminant gasses and result in low partial pressures for these gases.

At 330, the controller 120 may then control the transfer robot 164 to move the first substrate to a next PM or if processing of the first substrate is complete, perform a wafer exchange with the VTS 106. This includes returning the processed first substrate to the VTS and receiving another substrate from the VTS. During operation 330, a continuous purge flow of the backfill gas may be provided via the MFC 145 and the fourth valve 141 to further dilute any contaminant gases. In some embodiments, operation 302 may be performed subsequent to operation 330.

In one embodiment and during the above process, the water pump 134 may be continuously running after the roughing pump(s) reduce chamber pressure to the first chamber pressure and/or the PP H₂O to the first PP H₂O, as shown in FIG. 4. As a result, the water pump 134 continually removes water vapor that leaks in or outgasses into the VTM 102 independent of the chamber pressure and/or PP H₂O.

In some embodiments, the controller 120 is configured to provide both manual and/or automatic control of the chamber pressure. In some embodiments, controller 120 is configured to control valves, pumps, and backfill sources in order to achieve the desired chamber pressure based on an operator input or a stored recipe. In some embodiments, the controller may automatically perform pressure adjustment based on the pressure value detected by a pressure sensor (e.g., 172 in FIG. 1). In some embodiments, the controller may store various pressure settings for multiple recipes. This way, the pressure setting can be automatically identified upon selecting a recipe. In some embodiments, one or more alert indicators or alarms may be associated with the controller. The alert indicators may serve to provide notification when one or more steps are delayed or unable to complete, unable to reach the desired pressure (e.g., one or more steps in FIG. 3). In some embodiments, the alert indicators may provide a notification when the pump down or backfill time is longer than a predetermined threshold. For example, if an expected pump down time is about 74s with 2s variance, a notification may be generated when the pump down time is longer than 76s. In this situation, in some embodiments, the controller 120 may run a self-diagnostic to determine which component may have contributed to the issue (e.g., one of the vales or pumps).

Although the method of FIG. 3 and the plot of FIG. 4 are directed to the use of a water pump, similar operations may be performed without use of a water pump. For example, the turbo pump 132 may be used alone and the first, second, third and fourth PP H₂O may be higher than when a water pump is used. As another example, the second chamber pressure may be 3e−5 T instead of 5e−6 T. As another example, the turbo pump may be ran for longer periods of time and/or the first valve 136 may be held in an open state longer to allow pressures to be further reduced. As another example, a larger turbo pump and/or multiple turbo pumps may be used and connected in parallel to help make up for not using a water pump.

The substrate processing tool 100 of FIG. 1 allows, pumping down of the VTM 102 via the roughing pump 130 and the second valve 138 or via the turbo pump 132 and the first valve 136 during transfers between process operations that are not sensitive to water vapor and O₂. For example, the roughing pump 130 and the second valve 138 may be controlled (or regulated) when the chamber pressure is greater than 500 mT. The turbo pump and first valve 136 may be controlled (or regulated) when the chamber pressure is less than 500 mT and greater than 20-90 mT. This selectivity and controllability of VTM internal environment purity for each substrate transfer provides flexibility to minimize impact on throughput. The wide range of pressure selectivity also creates flexibility in what PMs are able to be implemented to solve application requirements.

In an embodiment, the method of FIG. 3 is performed when transferring a substrate from a first processing module configured to perform a pre-clean process to a second processing module configured to perform a deposition process. The pre-clean process may be performed to remove a native oxide layer on the substrate prior to metallization in the second processing module. The metallization (or deposition) process performed in the second processing module may be a physical vapor deposition (PVD), chemical vapor deposition (CVD) process or atomic layer deposition (ALD) process. In another embodiment, the method of FIG. 3 and/or a portion thereof is performed prior to performing a thin film deposition process in one of the processing modules. The thin film deposition process may include use of a precursor vapor chemistry that is sensitive to reaction with oxidizers, such as water vapor, diatomic oxygen, carbon dioxide, and carbon monoxide. By pumping down the VTM 102 to a low PP H₂O and then backfilling with an inert gas prior to interaction with the corresponding PM, the stated reaction with oxidizers is minimized.

FIG. 5 shows a substrate processing tool 500 configured to provide a low PP H₂O and O₂ environment. The substrate processing tool 500 is similar to the substrate processing tool 100 of FIG. 1, but instead of including a single roughing pump 130 the substrate processing tool 500 includes two roughing pumps (pumps 130 and 502), which are each controlled by the controller 120. Instead of the first roughing pump 130 drawing gas from the VTM 102 from valves 139 and 138, the first roughing pump 130 is used to draw gas from the third valve 139 and the second roughing pump 502 is used to draw gas from the second valve 138.

The substrate processing tool 500 includes the VTM 102, the multiple PMs 104, the VTS 106, and other tool modules 108. The controller 120 may control the pressure within the VTM 102 via two or more pumps (e.g., two or more of the roughing pumps 130, 502, the turbo pump 132, and the water pump 134) and multiple valves (e.g., the first valve 136, the second valve 138 and the third valve 139). In the example shown, the turbo pump 132, the first roughing pump 130 and the valves 136, 139 are connected in series. The second valve 138 and the second roughing pump 502 are connected in series and are in a separate independent pumping path than the valves 136, 139 and first roughing pump 130.

The substrate processing tool 500 may further include the MFC 145, the fourth valve 141, and the fifth valve 143, which receive gas from the backfill source 142. The water pump 134 includes the sealing plate 150 that is coupled to the cold plate 152. The water pump 134 is provided compressed helium (He) via the compressor 153 to cool the plate 152. The compressor 153 is connected to the water pump 134 with supply and return lines 155 and may be controlled by the controller 120. The substrate processing system 500 may further include the first flow restrictor 147 and the sixth valve 149.

The PMs 104 include respective processing chambers 158. The buffer 160 may be attached to the VTM 102 and store substrates. Access to the buffer 160 may be through the door 162. The transfer robot 164 is located within the VTM 102 and may be used to move substrates to and from the VTS 106, the PMs 104, and the buffer 160. In the example shown, the transfer robot 164 includes two end effectors 170.

The pressure sensor 172 may be attached to the VTM 102 and detect chamber pressure within the VTM 102. The controller 120 may adjust operation of the pumps 130, 132, 134, 502, the MFC 145 and/or states of the valves 136, 138, 139, 141, 143 based on an output of the pressure sensor 172. In another embodiment, the pumps 130, 132, 134, 402, the MFC 145 and/or valves 136, 138, 139, 141, 143 are controlled via a timing schedule. This control may be provided based on the output of the sensor 172 or independent of the output of the sensor 172. In one embodiment, one or more of the pumps 130, 132, 134, 502 are maintained in ON states and running and a chamber pressure within the VTM 102 is adjusted via the MFC 145 and the valves 136, 138, 139, 141, 143. In one embodiment, for example, the water pump 134 is maintained in an ON state and running. As another example, at least one or more of the roughing pumps 130, 502 and the turbo pump 132 is maintained in an ON state and running. The substrate processing tool 500 may include the RGA 180. The PMs 104 may have the pumping systems 190.

The temperature sensor 174 and/or the other sensors 176, such as the door sensors, may also be included. As with the embodiment of FIG. 1, the information detected by the sensors 174, 176 including the temperature of the cold plate 152 and/or water pump 134 and the state of the lid 178 of the VTM 102 may be used, for example, during operations performed to regenerate the water pump 134. An example water pump regeneration method is shown in FIG. 9. The user input device 179 may be included to receive an input to activate water pump regeneration. The water pump 134 may alternatively be regenerated automatically as described below.

The substrate processing tool 500 allows, pumping down of the VTM 102 via the roughing pump 502 and the second valve 138 or via the turbo pump 132 and the first valve 136 during transfers between process operations that are not sensitive to water vapor and O₂. For example, the roughing pump 502 and the valves 138 may be controlled (or regulated) when the chamber pressure is greater than 500 mT. The turbo pump and first valve 136 may be controlled (or regulated) when the chamber pressure is less than 500 mT and greater than 20-90 mT. This selectivity and controllability of VTM internal environment purity for each substrate transfer provides flexibility to minimize impact on throughput. The wide range of pressure selectivity also creates flexibility in what PMs are able to be implemented to solve application requirements.

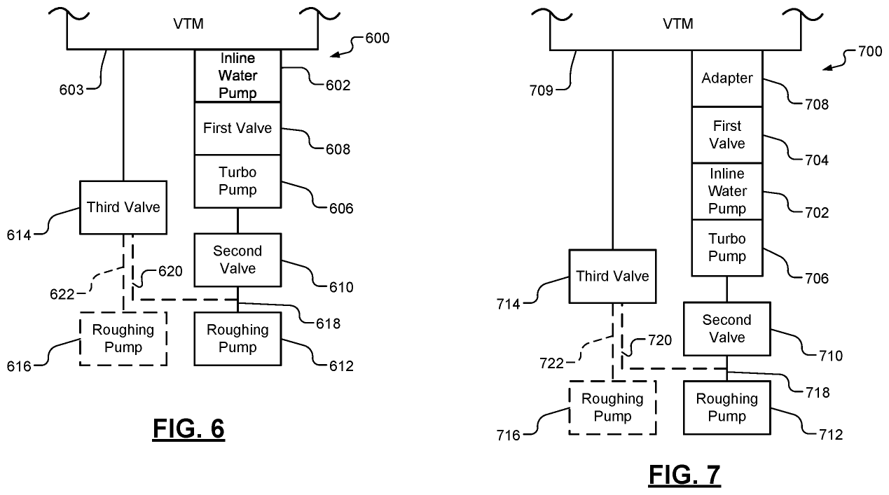

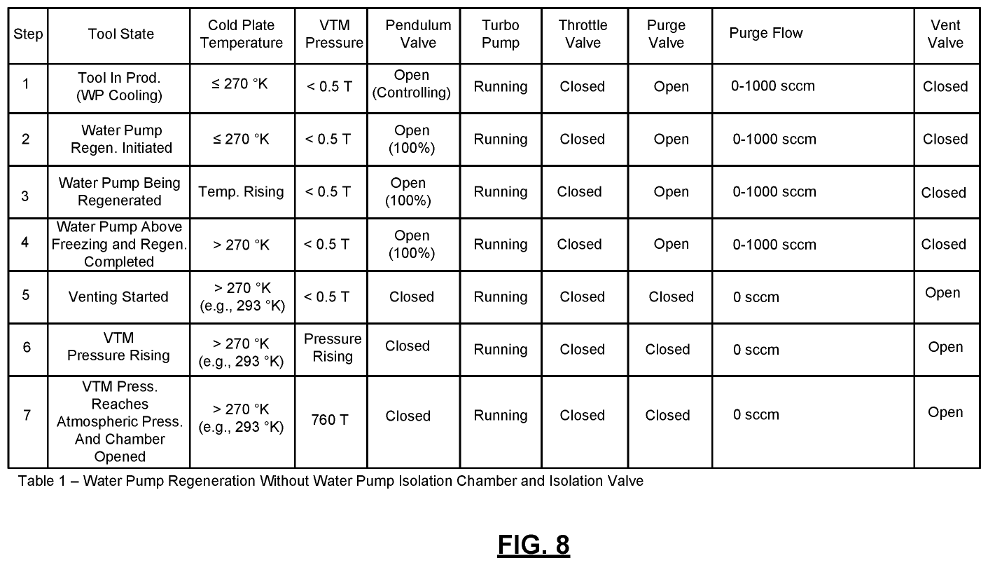

The following FIGS. 6-7 include alternative arrangements that may replace, for example, (i) the valves 136, 139, 138 and pumps 132, 130, 134 of FIG. 1, and/or (ii) the valves 136, 139, 138 and pumps 132, 130, 502, 134 of FIG. 5, according to some embodiments of the present disclosure.

FIG. 6 shows a portion of a substrate processing tool 600 that includes an inline water pump 602 disposed between a wall of a VTM (e.g., the VTM 102 of FIGS. 1 and 5) and a turbo pump 606. In some embodiments, the wall is one of the VTM's top or side walls. In some embodiments, the wall is a bottom wall 603 of the VTM. A first (or pendulum) valve 608 may be disposed between the inline water pump 602 and the turbo pump 606. The inline water pump 602 is coaxial with the turbo pump 606. In one embodiment, the inline water pump 602, the first valve 608 and the turbo pump 606 are stacked below the VTM such that the inline water pump 602 is directly connected to the bottom wall 603, the first valve 608 is directly connected to the inline water pump 602, and the turbo pump 606 is directly connected to the first valve 608. In an embodiment, an adapter is not connected between the inline water pump 602 and the bottom wall 603, as the inline water pump 602 is configured to directly connect to the bottom wall 603.

A second valve 610 may be connected to the turbo pump 606 and be disposed between the turbo pump 606 and a roughing pump 612. The roughing pump 612 may be connected to a third valve 614, which is connected to the bottom wall 603. As an alternative to the roughing pump 612 being connected to the valve 614, a second roughing pump 616 may connected to the valve 614. In one embodiment, both roughing pumps 612, 616 are included.

The second valve 610 may be connected to the roughing pump 612 via a line (or conduit) 618. In one embodiment, the turbo pump 606, the second valve 610 and the roughing pump 612 are stacked and directly connected together. The pumps 602, 606 and 612 and the valves 608, 610 are connected in series. The line 618 and/or the roughing pump 612 may be connected to the third valve via a line (or conduit) 620. The roughing pump 616 may be connected to the third valve 614 via a line (or conduit) 622.

The pumps 602, 606, 612, 616 and the valves 608, 610, 614 may be controlled by the controller 120 and be operated, in combination with the MFC 145, and valves 141, 143 of FIG. 1, in a similar manner as the other pumps and valves disclosed herein to provide, for example, the pressures control shown in FIG. 4 and referred to elsewhere herein. In some embodiments, the inline water pump 602 includes an internal cold plate (not shown) and may be operated in a similar manner as the water pump 134 of FIGS. 1 and 5. The turbo pump 606 may be operated in a similar manner as the turbo pump 132 of FIGS. 1 and 5. The roughing pumps 612, 616 may be operated in a similar manner as the roughing pumps 130, 502.

FIG. 7 shows a portion of a substrate processing tool 700 that includes an inline water pump 702 disposed between a first (or pendulum) valve 704 and a turbo pump 706. The inline water pump 702 is coaxial with the turbo pump 706. An adapter 708 may be disposed between a bottom wall 709 of a VTM (e.g., the VTM 102 of FIG. 1 or 5) and the valve 704. In one embodiment, the adapter 708, the first valve 704, the inline water pump 702, and the turbo pump 706 are stacked below the VTM such that the adapter 708 is directly connected to the bottom wall 709, the valve 704 is directly connected to the adapter 708, the inline water pump 702 is directly connected to the valve 704, and the turbo pump 706 is directly connected to the inline water pump 702. The adapter 708 allows the valve 704 to be connected to the bottom wall 709.

A second valve 710 may be connected to the turbo pump 706 and be disposed between the turbo pump 706 and a roughing pump 712. In one embodiment, the turbo pump 706, the second valve 710 and the roughing pump 712 are stacked and directly connected together. The adapter 708, the pumps 702, 706 and 712 and the valves 704, 710 are connected in series. The roughing pump 712 may be connected to a third valve 714, which is connected to the bottom wall 709. As an alternative to the roughing pump 712 being connected to the valve 714, a second roughing pump 716 may connected to the valve 714. In one embodiment, both roughing pumps 712, 716 are included.

The second valve 710 may be connected to the roughing pump 712 via a line (or conduit) 718. The line 718 and/or the roughing pump 712 may be connected to the third valve via a line (or conduit) 720. The roughing pump 716 may be connected to the third valve 714 via a line (or conduit) 722.

The pumps 702, 706, 712, 716 and the valves 704, 710, 714 may be controlled by the controller 120 and be operated, in combination with the MFC 145, and valves 141, 143 of FIG. 1, in a similar manner as the other pumps and valves disclosed herein to provide, for example, the pressures control shown in FIG. 4 and referred to elsewhere herein. The inline water pump 702 includes an internal cold plate (not shown) and may be operated in a similar manner as the water pump 134 of FIGS. 1 and 5. The turbo pump 706 may be operated in a similar manner as the turbo pump 132 of FIGS. 1 and 5. The roughing pumps 712, 716 may be operated in a similar manner as the roughing pumps 130, 502.

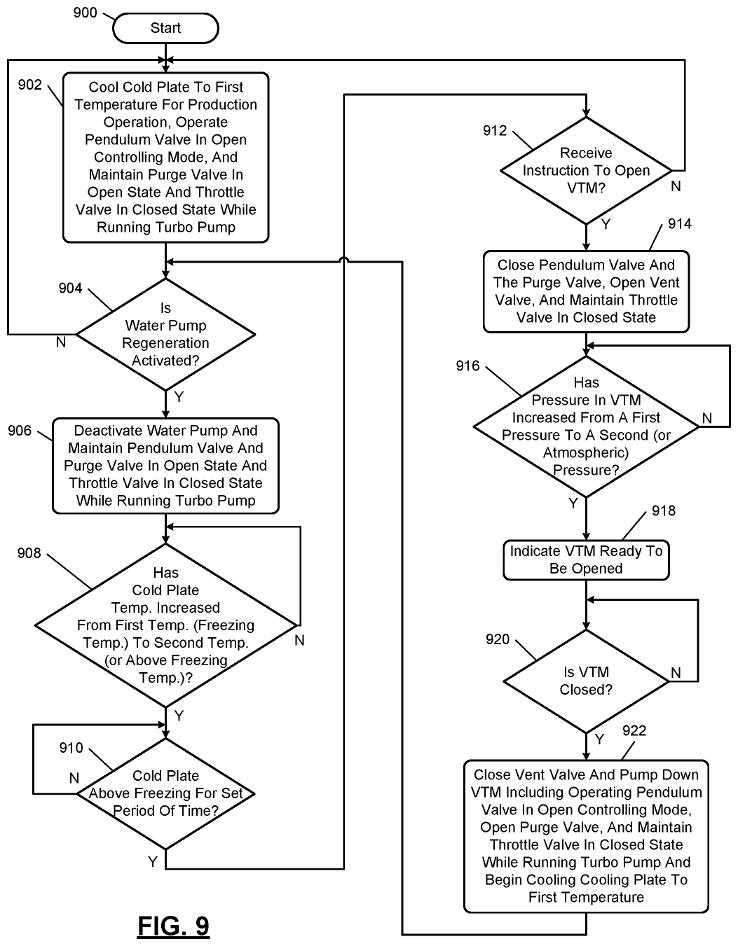

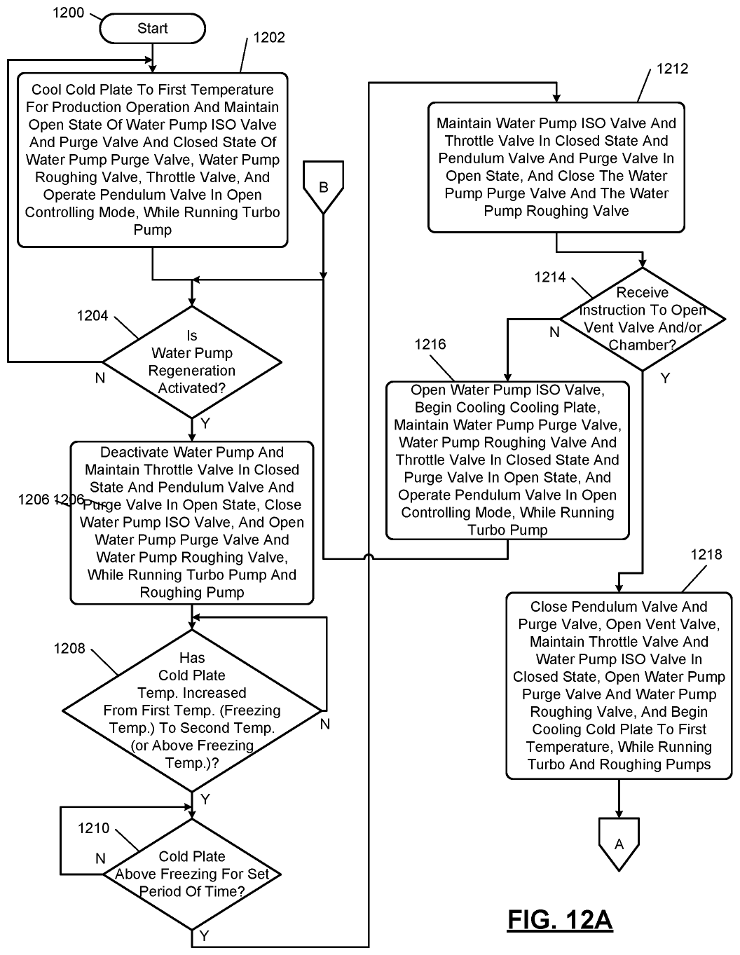

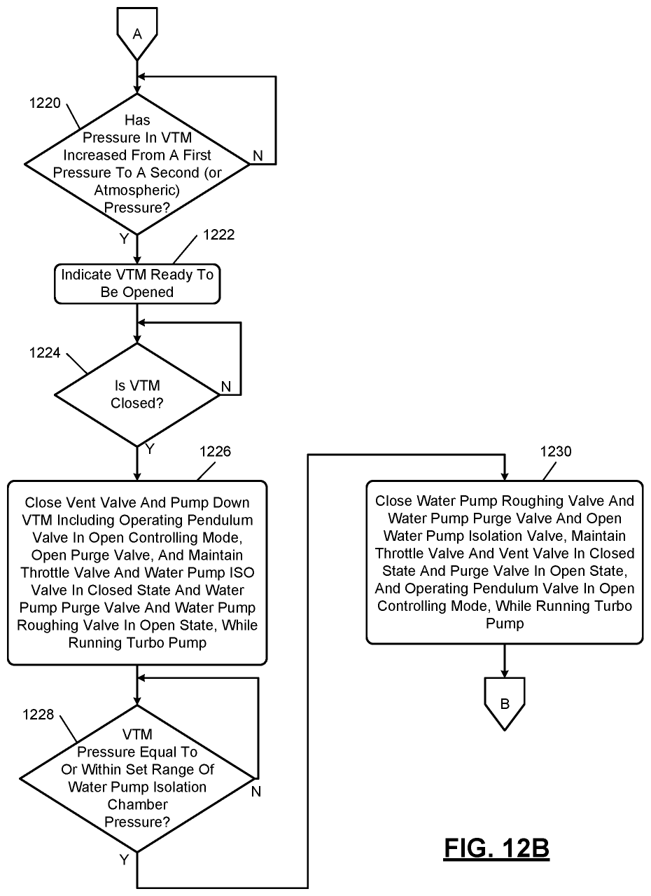

The tables of FIGS. 8 and 11 and the methods of FIGS. 9 and 12 include implementation of multiple steps and operations. These steps and operations include running the turbo pump 132. When the turbo pump 132 is running, the third valve 139 is open and the roughing pump 130 is also running. The methods of FIGS. 9 and 12 may be performed prior to or subsequent to performing the other methods disclosed herein.

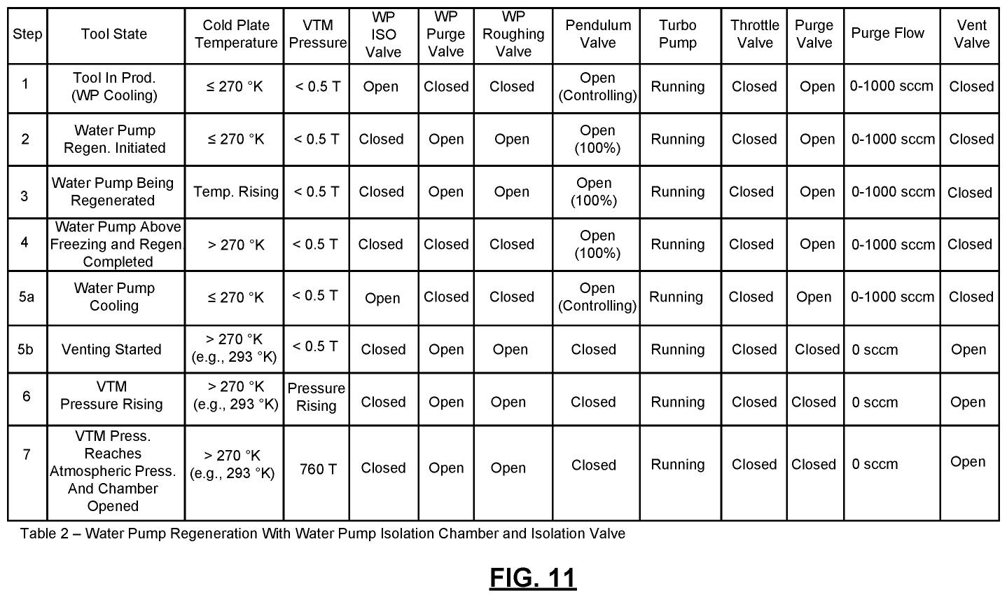

FIG. 8 shows a first table of operations performed prior to and during water pump regeneration. The steps of the first table may be implemented during the method of FIG. 9 and may be performed by, for example, the substrate processing systems 100 and 500 of FIGS. 1 and 5. Steps 1-4 may be performed to regenerate the water pump without use of a water pump isolation chamber and/or water pump isolation valve, such as that shown in FIG. 10. Steps 5-7 may be performed when, for example, performing maintenance on an interior of the VTM 102. The pressure within the VTM 102 is increased to atmospheric pressure and the VTM 102 is opened to the atmosphere.

Regenerating the water pump 134 includes increasing temperature of the cold plate 152 of FIGS. 1 and/or 5 from a temperature at or below freezing (e.g., 270 degrees Kelvin (° K)) to a temperature above freezing (e.g., ambient temperature or 293° K). Over time layers of ice build up on the cold plate 152. The more layers that build up, the less effective the cold plate is in collecting water. Regeneration is performed to remove these layers and return the cold plate 152 to a baseline condition, where it is most effective in removing water. During step 1, the substrate processing system (or tool) is processing substrates (referred to as “in production”) and the water pump 134 is cooling the cold plate 152 to collect water. In step 2, regeneration is initiated and the water pump 134 is deactivated and thus is no longer cooling the cold plate 152. The temperature of the cold plate 152 thus rises during step 3 to temperatures above freezing. During step 3, water coming off of the cold plate 152 is drawn out of the VTM 102 via the first (or pendulum) valve 136 and the turbo pump 132. At step 4, the cold plate 152 is at a peak temperature (e.g., ambient temperature) and regeneration is completed.

When the VTM 102 is to be opened, the vent (or sixth) valve 149 is opened at step 5. This increases pressure within the VTM 102 to allow the VTM 102 to be opened. Pressure in the VTM 102 is increased from being less than 0.5 T to atmospheric pressure (or 760 T). During step 6, pressure is rising until at step 7 pressure is at atmospheric pressure and the VTM 102 is opened (e.g., the lid 178 is opened to the atmosphere). During steps 1-4, the pendulum valve 136 is open. During steps 5-7, the pendulum valve 136 is closed. Purge flow in Table 1 refers to flow through the purge valve 141.

FIG. 9 shows a method of performing water pump regeneration without use of a water pump isolation chamber and isolation valve. The method of FIG. 9 corresponds to Table 1 and may be implemented using the substrate processing system 100 or 500 of FIGS. 1 and 5. The method may be implemented by the controller 120.

The method may begin at 900. At 902, the cold plate 152 is cooled to a first selected temperature at or below a freezing temperature (e.g., less than or equal to 270° K) for production operation. Step 902 corresponds to step 1 in Table 1. The pendulum valve 136 is operated in an open controlling mode, where the pendulum valve 136 is at least partially open and the amount that the pendulum valve 136 is open may vary. The purge valve 141 is open (e.g., fully open) and the throttle valve 138 is closed. The turbo pump 132 is running.

At 904, the controller 120 determines whether water pump regeneration is activated. If activated, operation 906 may be performed, otherwise operation 902 may be performed. Water pump regeneration may be activated by a user via the user input device 179 or automatically. For example, the controller 120 may regenerate the water pump 134 after (i) the water pump has been running for a predetermined period of time, and/or (ii) a predetermined number of substrates have been processed during which the water pump has been running.

At 906, the controller 120 deactivates the water pump 134, maintains the pendulum valve 136 and the purge valve 141 in an open state, and maintains the throttle valve 138 in a closed state. The turbo pump 132 may be maintained in a running state.

At 908, the controller 120 determines whether a temperature of the cold plate 152 has increased from a first temperature at or below freezing to a second temperature above freezing. If yes, operation 910 may be performed. At 910, the controller 120 may determine whether the cold plate is above freezing for a set period of time. This set period of time assures that the ice on the cold plate 152 has melted. If above freezing for the set period of time, operation 912 may be performed.

At 912, the controller 120 determines whether an instruction has been received to open the VTM 102. This may be from, for example, the input device 179. If an instruction has been received, operation 914 is performed, otherwise operation 902 may be performed. At 914, the controller 120 closes the pendulum valve 136 and the purge valve 141, opens the vent valve 149, and maintains the throttle valve 138 in a closed state. In an embodiment, the pendulum valve 136 is closed prior to opening the vent valve 149. The turbo pump 132 is kept running. This minimizes time to pump down the VTM 102 when the VTM 102 is later closed.

At 916, the controller 120 determines whether pressure in the VTM 102 is increased from a first pressure to a second (or atmospheric) pressure. If yes, operation 918 may be performed. At 918, the controller 120 may indicate that the VTM 102 is ready to be opened. This may be done, for example, via the input device 179.

At 920, the controller 120 may determine if the VTM 102 is closed. If yes, operation 922 is performed. At 922, the controller 120 closes the vent valve 149 and pumps down the VTM 102 including operating the pendulum valve 136 in the open controlling mode. The purge valve 141 is opened and the throttle valve 138 is maintained in a closed state. The turbo pump 132 is maintained in a running state to pump down the VTM 102. The water pump 134 is activated to begin cooling the cold plate to the first (or below freezing) temperature. Operation 904 may be performed subsequent to operation 922.

FIG. 10 shows a substrate processing tool 1000 including a VTM 1001 separated from a water pump isolation chamber 1002 via a water pump isolation valve 1004. Although the substrate processing tool 1000 is configured similarly as the substrate processing system 100 of FIG. 1, it may be configured similarly as the substrate processing system 500 of FIG. 5. The substrate processing system 1000 further includes the VTS 106, other tool modules 108, the processing chambers 158, and the buffer 160. The doors 110 are located between the VTM 1001 and the processing chambers 158. The door 162 is located between the VTM 1001 and the buffer 160. The substrate processing system 1000 further includes the roughing pump 130, turbo pump 132, valves 136, 138, 139, 141, 143, 149, backfill source 142, MFC 145, restrictor 147, lid 178, RGA 180 and pumping systems 190.

The substrate processing system 1000 further includes a water pump 1010 with a cold plate 1012, a cold head 1014 and a sealing plate 1016. The water pump 1010 is connected to the compressor 153. The water pump isolation valve 1004 is used to separate the cold plate 1012 from the interior of the VTM 1001 during regeneration of the cold plate 1012. The controller 120 controls regeneration of the cold plate 1012 based on feedback from the sensors 172, 174, 176 and a vacuum sensor (or switch) 1020. The vacuum sensor 1020 may be used to determine the pressure in the water pump isolation chamber 1002. The controller 120 may open the water pump isolation valve 1004 based on a difference between a pressure in the VTM 1001 and the pressure in the water pump isolation chamber 1002. If the vacuum sensor 1020 is configured to operate as a vacuum switch, then when a pressure in the water pump isolation chamber 1002 is under vacuum, the controller 120 may prevent opening the water pump isolation valve 1004 until the pressure in the VTM 1001 matches or is within a set range from the pressure in the water pump isolation chamber 1002.

The substrate processing system 1000 further includes a seventh (or water pump roughing) valve 1030, a second flow restrictor 1032, an eighth (or water pump purge) valve 1034, and a pressure regulator 1036. The second flow restrictor 1032, the water pump purge valve 1034, and the pressure regulator 1036 are connected in series between the backfill source 142 and the water pump isolation chamber 1002. The water pump roughing valve 1030 is opened when drawing fluids from within the water pump isolation chamber 1002. The water pump purge valve 1034 is open when the water pump isolation chamber 1002 is being purged. The pressure regulator 1036 regulates flow of fluids to the water pump isolation chamber 1002. The restrictor 1032 restricts flow of fluids to the water pump isolation chamber 1002.

In Table 2, purge flow refers to flow through the purge valve 141. When the water pump purge valve 1034 is open, purge flow through the water pump purge valve 1034 may also be 0-1000 sccm.

FIG. 11 shows a second table including operations performed prior to, during and subsequent to water pump regeneration. The steps of the second table may be implemented during the method of FIG. 12 and may be performed by, for example, the substrate processing systems 1000 of FIG. 10. Steps 1-4 may be performed to regenerate the water pump using of the water pump isolation chamber 1002 and water pump isolation valve 1004, as shown in FIG. 10. Step 5a may be performed when the VTM 1001 is not to be opened. Steps 5b-7 may be performed when, for example, performing maintenance on an interior of the VTM 1001. The pressure within the VTM 1001 is increased to atmospheric pressure and the VTM 1001 is opened to the atmosphere.

Regenerating the water pump 1010 includes increasing temperature of the cold plate 1012 of FIG. 10 from a temperature at or below freezing (e.g., 270 degrees Kelvin (° K)) to a temperature above freezing (e.g., ambient temperature or 293° K). Regeneration is performed to remove ice layers built up on the cold plate 1012 and return the cold plate 1012 to a baseline condition, where it is most effective in removing water. During step 1, the substrate processing system 1000 (or tool) is processing substrates (referred to as in production) and the water pump 1010 is cooling the cold plate 1012 to collect water. The water pump (WP) isolation valve 1004 is open and the WP roughing valve 1030 and WP purge valve 1034 are closed.

In step 2, regeneration is initiated and the water pump 1010 is deactivated and thus is no longer cooling the cold plate 1012. The WP isolation valve 1004 is closed and the WP roughing valve 1030 and WP purge valve 1034 are opened. The temperature of the cold plate 1012 thus rises during step 3 to temperatures above freezing. During step 3, water coming off of the cold plate 1012 is drawn out of the WP isolation chamber 1002 via the WP roughing valve 1030 and the roughing pump 130. The valves 1030, 1034 are open. At step 4, the cold plate is at a peak temperature (e.g., ambient temperature) and regeneration is completed. The valves 1030, 1034 are closed. At step 5a, the water pump is reactivated and begins cooling the cold plate 1012. The WP isolation valve 1004 is opened. This allows the cold plate 1012 to draw water from within the VTM 1001.

When the VTM 1001 is to be opened, the vent (or sixth) valve 149 is opened at step 5b. The valves 1030, 1034 are opened. The WP isolation valve 1004 remains closed. This increases pressure within the VTM 102 to allow the VTM 102 to be opened. Pressure in the VTM 102 is increased from being less than 0.5 T to atmospheric pressure (or 760 T). During step 6, pressure is rising until at step 7 pressure is at atmospheric pressure and the VTM 102 is opened (e.g., the lid 178 is opened to the atmosphere). During steps 1-4, the pendulum valve 136 is open. During steps 5-7, the pendulum valve 136 is closed.

FIG. 12 shows a method of performing water pump regeneration with use of a water pump isolation valve. The method of FIG. 12 corresponds to the second table of FIG. 11 and may be implemented using the substrate processing system 1000 of FIG. 10. The method may be implemented by the controller 120.

The method may begin at 1200. At 1202, the cold plate 152 is cooled to a first selected temperature at or below a freezing temperature (e.g., less than or equal to 270° K) for production operation. Step 1202 corresponds to step 1 in Table 2. The WP isolation valve 1004 is maintained in an open state. The pendulum valve 136 is operated in an open controlling mode, where the pendulum valve 136 is at least partially open and the amount that the pendulum valve 136 is open may vary. The purge valve 141 is open (e.g., fully open) and the WP purge valve 1034, the WP roughing valve 1030, and the throttle valve 138 are maintained in a closed state. The turbo pump 132 is running.

At 1204, the controller 120 determines whether water pump regeneration is activated. If activated, operation 1206 may be performed, otherwise operation 1202 may be performed. Water pump regeneration may be activated by a user via the user input device 179 or automatically, as described above.

At 1206, the controller 120 deactivates the water pump 134, maintains the pendulum valve 136 and the purge valve 141 in an open state and the throttle valve 138 in a closed state. In an embodiment, the WP isolation valve 1004 is closed and then the valves 1030, 1034 are opened. The turbo pump 132 may be maintained in a running state. The roughing pump 130 may be running during this operation. Closing the WP isolation valve 1004 prevents water from the cold plate 1012 from entering the VTM 1001. In addition, by opening the valves 1030, 1034 and running the roughing pump 130 water is drawn from the water pump isolation chamber 1002.

At 1208, the controller 120 determines whether a temperature of the cold plate 152 has increased from a first temperature at or below freezing to a second temperature above freezing. If yes, operation 1210 may be performed. At 1210, the controller 120 may determine whether the cold plate is above freezing for a set period of time. This set period of time assures that the ice on the cold plate 152 has melted. If above freezing for the set period of time, operation 1212 may be performed.

At 1212, the controller 120 maintains the WP isolation valve 1004 and the throttle valve 1038 in a closed state and the pendulum valve 136 and purge valve 141 in an open state. The valves 1030, 1034 are closed.

At 1214, the controller 120 determines whether an instruction has been received to open the VTM 1001. This may be from, for example, the input device 179. If yes, operation 1218 is performed, otherwise operation 1216 is performed.

At 1216, the controller 120 opens the WP isolation valve 1004, begins cooling the cold plate 1012, maintains the valves 1030, 1034, 1038 in a closed state, and maintains the purge valve 141 in an open state. The pendulum valve 136 is operated in the open controlling mode.

At 1218, the controller 120 closes the pendulum valve 136 and purge valve 141, opens the vent valve 149, maintains the throttle valve 138 and WP isolation valve 1004 in a closed state, and opens the WP roughing valve 1030 and WP purge valve 1034. In an embodiment, the pendulum valve 136 is closed prior to opening the vent valve. The roughing pump 130 may be running during this operation. By having the valves 1030, 1034 open, the water pump isolation chamber 1002 is maintained at a pressure below atmospheric pressure (e.g., at a pressure less than 0.5 T). This occurs while the VTM 1001 is open. This reduces pump down time when the VTM 1001 is later closed. The water pump 134 is activated to begin cooling the cold plate 1012 to the first (or below freezing) temperature. This minimizes time to cool the cold plate 1012 when the VTM 1001 is later closed and protects the cold plate 1012 from ambient moisture.

At 1220, the controller 120 determines whether pressure in the VTM 1001 is increased from a first pressure to a second (or atmospheric) pressure. If yes, operation 1222 may be performed. At 1222, the controller 120 may indicate that the VTM 1001 is ready to be opened. This may be done, for example, via the input device 179.

At 1224, the controller 120 may determine if the VTM 1001 is closed. If yes, operation 1226 is performed. At 1226, the controller 120 closes the vent valve 149 and pumps down the VTM 1001 including operating the pendulum valve 136 in the open controlling mode. The purge valve 141 is opened and the throttle valve 138 and WP ISO valve are maintained in a closed state. The valves 1030, 1034 are maintained in an open state. The turbo pump 132 is maintained in a running state to pump down the VTM 102. Operation 1228 may be performed subsequent to operation 1226.

At 1228, the controller 120 may determine whether a pressure in the VTM is equal to or within a set range of a pressure in the WP isolation chamber 1002. If yes, operation 1230 is performed. At 1230, the controller 120 closes the valves 1030, 1034 and opens the WP isolation valve 1004. The controller 120 maintains the throttle valve 138 and vent valve 149 in a closed state and the purge valve 141 in an open state. The pendulum valve 136 is operated in the open controlling mode and the turbo pump is running. Operation 1204 may be performed subsequent to operation 1230.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A substrate processing tool comprising:
a first processing module;
a substrate transfer chamber connected to the first processing module;
one or more pumps;
a backfill source;
a plurality of valves connected to the one or more pumps and the backfill source; and
one or more controllers configured to
control the one or more pumps and the plurality of valves to reduce a chamber pressure in the substrate transfer chamber from a first chamber pressure to a second chamber pressure and then backfill the substrate transfer chamber with an inert gas to a third chamber pressure prior to permitting transfer of a substrate into the first processing module,
subsequent to backfilling the substrate transfer chamber, cause a transfer of the substrate from the substrate transfer chamber to the first processing module, and
cause the first processing module to process the substrate.

2. (canceled)

3. The substrate processing tool of claim 1, wherein:
the one or more pumps comprise a first pump;
the plurality of valves comprise a first valve connected to the first pump and the substrate transfer chamber; and
the one or more controllers are configured to control a state of the first valve to pump down to the second chamber pressure.

4-5. (canceled)

6. The substrate processing tool of claim 1, further comprising a mass flow controller, wherein:
one of the plurality of valves is connected in series with the mass flow controller and between the backfill source and the substrate transfer chamber, wherein the mass flow controller is configured to adjust flow of the inert gas from the backfill source to the substrate transfer chamber; and
the one or more controllers are configured to control operation of the mass flow controller and the one of the plurality of valves to supply the inert gas to backfill the substrate transfer chamber to the third chamber pressure.

7. The substrate processing tool of claim 1, further comprising a plurality of processing modules comprising the first processing module and a second processing module, wherein:
the plurality of processing modules are configured to perform different respective types of substrate processing; and
the substrate transfer chamber is connected to the plurality of processing modules, wherein the substrate transfer chamber is configured to transfer the substrate from the first processing module to the second processing module.

8-11. (canceled)

12. The substrate processing tool of claim 1, wherein the one or more controllers are configured to:
while reducing the chamber pressure in the substrate transfer chamber, control the one or more pumps and the plurality of valves to reduce a partial pressure of oxygen (PP O₂) in the substrate transfer chamber from a first PP O₂ to a second PP O₂; and
while backfilling the substrate transfer chamber to the third chamber pressure, backfill the substrate transfer chamber to a third PP O₂ prior to permitting transfer of the substrate into the first processing module.

13-20. (canceled)

21. The substrate processing tool of claim 1, wherein the one or more controllers are configured to:
while reducing the chamber pressure in the substrate transfer chamber, control the one or more pumps and the plurality of valves reduce a partial pressure of water vapor (PP H₂O) in the substrate transfer chamber from a first PP H₂O to a second PP H₂O; and
while backfilling the substrate transfer chamber to the third chamber pressure, control the plurality of valves to backfill the substrate transfer chamber to a third PP H₂O prior to permitting transfer of the substrate into the first processing module.

22-30. (canceled)

31. The substrate processing tool of claim 1, wherein the one or more pumps comprise:
a turbo pump; and
an inline water pump connected in series between the substrate transfer chamber and the turbo pump,
wherein one of the plurality of valves
is connected in series between the inline water pump and the turbo pump.

32. The substrate processing tool of claim 1, further comprising an adapter connected to the substrate transfer chamber, wherein:
the one or more pumps comprise
a turbo pump, and
an inline water pump connected in series between the substrate transfer chamber and the turbo pump; and
one of the plurality of valves is connected in series between the adapter and the inline water pump.

33. The substrate processing tool of claim 1, wherein the first processing module is configured to perform a thin film deposition process using a precursor vapor that is sensitive to reactions with oxidizers.

34. The substrate processing tool of claim 1, wherein the one or more pumps include a turbo pump and a water pump.

35. The substrate processing tool of claim 1, wherein the one or more pumps include a turbo pump and not a water pump.

36. The substrate processing tool of claim 1, wherein the one or more pumps include a water pump.

37. The substrate processing tool of claim 1, wherein the one or more pumps include only a single pump.

38. The substrate processing tool of claim 1, wherein the one or more pumps include two or more pumps for pumping gases from the substrate transfer chamber.

39. The substrate processing tool of claim 1, wherein the inert gas comprises argon gas.

40. A substrate processing tool comprising:
a first processing module;
a substrate transfer chamber connected to the first processing module;
one or more pumps;
a backfill source; and
one or more controllers configured to
control the one or more pumps to change at least one of a partial pressure of oxygen (PP O₂) and a partial pressure of water vapor (PP H₂O) in the substrate transfer chamber from a first partial pressure to a second partial pressure and then backfill the substrate transfer chamber with an inert gas to a third partial pressure prior to permitting transfer of a substrate into the first processing module,
subsequent to backfilling the module substrate transfer chamber, cause transfer of the substrate from the substrate transfer chamber to the first processing module, and
cause the first processing module to process the substrate.

41. The substrate processing tool of claim 40, further comprising a plurality of valves connected to the one or more pumps and the backfill source,
wherein the one or more controllers configured to control the one or more pumps and the plurality of valves to reduce the PP O₂ in the substrate transfer chamber from the first partial pressure to the second partial pressure and then backfill the substrate transfer chamber with the inert gas to the third partial pressure prior to permitting transfer of the substrate into the first processing module.

42. (canceled)

43. The substrate processing tool of claim 40, further comprising a plurality of valves connected to the one or more pumps and the backfill source,
wherein the one or more controllers is configured to control the one or more pumps and the plurality of valves to reduce the PP H₂O in the substrate transfer chamber from the first partial pressure to the second partial pressure and then backfill the substrate transfer chamber with the inert gas to the third partial pressure prior to permitting transfer of the substrate into the first processing module.

44. The substrate processing tool of claim 40, wherein the one or more controllers is configured to adjust the PP H₂O in the substrate transfer chamber based on a chamber pressure of the substrate transfer chamber.

45. A method of operating a substrate processing tool, the method comprising:
receiving a substrate at a substrate transfer chamber, wherein the substrate transfer chamber is connected to a first processing module and a second processing module;
pumping, via one or more pumps, the substrate transfer chamber down from a first chamber pressure to a second chamber pressure;
backfilling the substrate transfer chamber with an inert gas from the second chamber pressure to a third chamber pressure;
transferring the substrate from the substrate transfer chamber to the first processing module;
performing a first type of substrate process on the substrate in the first processing module;
subsequent to processing the substrate in the first processing module, transferring the substrate from the first processing module back to the substrate transfer chamber;
backfilling the substrate transfer chamber with the inert gas from the third chamber pressure to the first chamber pressure; and
transferring the substrate from the substrate transfer chamber to the second processing module.

46. The method of claim 45, further comprising maintaining the third chamber pressure in the substrate transfer chamber while processing the substrate in the first processing module.

47. The method of claim 45, further comprising:
pumping the substrate transfer chamber down to the second chamber pressure comprises pumping down the substrate transfer chamber from a first partial pressure of oxygen (PP O₂) to a second PP O₂;
backfilling the substrate transfer chamber with the inert gas to the third chamber pressure comprises backing filling the substrate transfer chamber from the second PP O₂ to a third PP O₂; and
backfilling the substrate transfer chamber with the inert gas to the first chamber pressure comprises backfilling the substrate transfer chamber from the third PP O₂ to the first PP O₂.

48. (canceled)

49. The method of claim 45, further comprising:
pumping the substrate transfer chamber down to the second chamber pressure comprises pumping down the substrate transfer chamber from a first partial pressure of oxygen (PP H₂O) to a second PP H₂O;
backfilling the substrate transfer chamber with the inert gas to the third chamber pressure comprises backing filling the substrate transfer chamber from the second PP H₂O to a third PP H₂O; and
backfilling the substrate transfer chamber with the inert gas to the first chamber pressure comprises backfilling the substrate transfer chamber from the third PP H₂O to the first PP H₂O.

50-62. (canceled)

63. The substrate processing tool of claim 1, wherein the substrate transfer chamber is a vacuum transfer module.

64. The substrate processing tool of claim 40, wherein the one or more controllers are configured to reduce the at least one of the PP O₂ and PP H₂O by at least one of i) controlling the one or more pumps, and ii) backfilling the substrate transfer chamber with inert gas.
